(19) United States
(12) Patent Application Publication
(10) Pub. No.: US 2025/0113475 A1
(43) Pub. Date: Apr. 3, 2025

(54) ELECTROMAGNETIC WAVE ATTENUATION FILM AND MANUFACTURING METHOD OF SAME

(71) Applicant: TOPPAN HOLDINGS INC, Tokyo (JP)

(72) Inventors: Atsuko AOKI, Tokyo (JP); Shinpei KONDO, Tokyo (JP); Toru FUJITA, Tokyo (JP); Miho IMAI, Tokyo (JP); Ryosuke KOTAKA, Tokyo (JP)

(73) Assignee: TOPPAN HOLDINGS INC, Tokyo (JP)

(21) Appl. No.: 18/953,890

(22) Filed: Nov. 20, 2024

Related U.S. Application Data
(63) Continuation of application No. PCT/JP2023/018861, filed on May 22, 2023.

(30) Foreign Application Priority Data
May 23, 2022 (JP) 2022-083527
May 23, 2022 (JP) 2022-083534
Sep. 8, 2022 (JP) 2022-142826
Sep. 8, 2022 (JP) 2022-142832
Nov. 28, 2022 (JP) 2022-188877
Mar. 20, 2023 (JP) 2023-044023
Mar. 20, 2023 (JP) 2023-044034

(51) Int. Cl. H05K 9/00

(52) U.S. Cl. CPC H05K 9/0081

(57) ABSTRACT

A electromagnetic wave attenuation film includes a substrate provided with a dielectric substrate having a front surface and a back surface, and thin film conductive layers arranged on both the front surface and the back surface of the electromagnetic wave attenuation substrate; a support layer arranged on the back surface of the electromagnetic wave attenuation substrate; and a flat plate inductor arranged on the back surface of the support layer; wherein the thin film conductive layers include a plurality of conductive elements. Furthermore, the conductive elements are arranged periodically, and when a distance in a plane direction between a center of gravity of the conductive elements on the front surface and the back surface is 1, and a shortest distance from the center of gravity of the conductive elements to a plate end portion is a, equation (1) below may be satisfied. I≤5.2a . . . (1)

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2023/018861, filed on May 22, 2023, which is based upon and claims the benefit to Japanese Patent Application No. 2022-083527, filed on May 23, 2023; Japanese Patent Application No. 2022-083534, filed on May 23, 2023; Japanese Patent Application No. 2022-142826, filed on Sep. 8, 2022; Japanese Patent Application No. 2022-142832, filed on Sep. 8, 2022; Japanese Patent Application No. 2022-188877, filed on Nov. 28, 2022; Japanese Patent Application No. 2023-044023, filed on Mar. 20, 2023; Japanese Patent Application No. 2023-044034, filed on Mar. 20, 2023; the disclosures of all which are incorporated herein by reference in their entirety.

### TECHNICAL FIELD

The present invention relates to an electromagnetic wave attenuation film that is capable of capturing incident waves and attenuating reflected waves, and a manufacturing method of the same.

### BACKGROUND

Radio waves having a frequency band of several gigahertz (GHz) are used in mobile communications such as mobile phones, wireless LANs, and electronic toll collection systems (ETC).

As a radio wave absorption sheet that absorbs such radio waves, Non-Patent Literature 1 proposes a radio wave absorber that has a plurality of metal patterns periodically arranged in two layers, in which the radio wave absorber exhibits absorption characteristics in two bands due to circular metal patterns with slightly different diameters being arranged in the different layers.

[Citation List][Non-Patent Literature] Non Patent Literature 1: Journal of Institute of Electronics, Information and Communication Engineers B, Vol. J103-B, No. 12, pp. 684-686

### SUMMARY OF THE INVENTION

### Technical Problem

However, when a conductive element is provided on one side of a substrate, and the radio wave absorber is produced by stacking a plurality of such layers to form an absorption layer, stretching or bending of the laminate film on which the conductive element is provided can cause a shift in the positional accuracy between layers, resulting in a shift in the absorption frequency. The absorber proposed in Non-Patent Literature 1 has a problem in that dielectric substrates such as FR4, on which a predetermined conductive pattern has been formed, must be attached to each other and laminated with high accuracy. When using a material as a substrate film that easily stretches and contracts, such as a resin sheet, rather than a rigid body such as glass, it is very difficult to attach two substrate films to each other with an accuracy within several tens to several m which allows the desired characteristics to be obtained.

In addition, there is a concern that the frequency characteristics and the angular characteristics may change due to positional shift between the elements caused by deterioration over time of the stacked parts. Also, from the viewpoint of processing and cost, an increase in the number of substrate sheets on which elements are provided is not preferable.

The present invention has an object of solving such conventional problems, and easily and inexpensively obtaining an electromagnetic wave attenuation film with little shift in the absorption peak frequency, and little change in the frequency characteristics and angular characteristics over time.

### Solution to Problem

In order to solve the problem described above, a representative electromagnetic wave attenuation film of the present invention includes: an electromagnetic wave attenuation substrate provided with a dielectric substrate having a front surface and a back surface, and thin film conductive layers arranged on both the front surface and the back surface of the electromagnetic wave attenuation substrate; a support layer arranged on the back surface of the electromagnetic wave attenuation substrate; and a flat plate inductor arranged on a back surface of the support layer; wherein the thin film conductive layers include a plurality of conductive elements.

### Advantageous Effects of the Invention

According to the present invention, it is possible to provide an electromagnetic wave attenuation film that is capable of attenuating radio waves in a millimeter wave band frequency, and is thin. Furthermore, by simultaneously forming the thin film conductive layers on the front surface and the back surface of a single-layer substrate, it is possible to ensure the positional accuracy of the thin film conductive layers, and to easily manufacture an electromagnetic wave attenuation film that exhibits absorption performance at a target frequency.

### BRIEF DESCRIPTION OF THE DRAWINGS

FIG. 1 is a schematic plan view showing an electromagnetic wave attenuation film according to a first embodiment of the present invention.

FIG. 2 is a schematic view showing a portion of the cross-section taken along line I-I of FIG. 1.

FIG. 3 is a cross-sectional view of a case in which thin film conductive layers are arranged and patterned on a dielectric body via a pressure-sensitive adhesive layer.

FIG. 4 is a cross-sectional view of a case where a flat plate inductor is formed having a mesh shape.

FIGS. 5A and 5B are schematic views showing examples of planar view shapes of a thin film conductive layer.

FIG. 6 is a schematic view showing examples of combinations of planar view shapes of a thin film conductive layer.

FIG. 7 is a graph showing the relationship between the dimensions of a conductive element and the wavelength of attenuated electromagnetic waves.

FIG. 8 is an image showing a simulation result of the electric field intensity according to one example of a distance between conductive elements on the front surface and conductive elements on the back surface.

FIG. 9 is an image showing a simulation result of the electric field intensity according to another example of a distance between conductive elements on the front surface and conductive elements on the back surface.

FIGS. 10A and 10B are schematic plan views showing an electromagnetic wave attenuation film according to an applied mode of the first embodiment of the present invention.

FIG. 11 is a graph showing a simulation result of the attenuation properties of an electromagnetic wave depending on changes in the thickness of a conductive element.

FIG. 12 is a schematic plan view showing an electromagnetic wave attenuation film according to a second embodiment of the present invention.

FIG. 13 is a schematic view showing a portion of a cross-section taken along line II-II in FIG. 11.

FIG. 14 is a schematic view of an example showing a portion of a cross-section taken along line I-I in FIG. 1 in a case where blackening layers are provided.

FIG. 15 is a schematic view of another example showing a portion of a cross-section taken along line I-I in FIG. 1 in a case where blackening layers are provided.

FIG. 16 is a schematic view of another example showing a portion of a cross-section taken along line I-I in FIG. 1 in a case where blackening layers are provided.

FIG. 17 is a schematic view showing a portion of a cross-section taken along line I-I in FIG. 1 in a case where a top coat layer is provided.

FIG. 18 is a schematic diagram showing a simultaneous exposure step.

FIG. 19 is a schematic diagram showing a portion of a cross-section of the electromagnetic wave attenuation films described in Examples 1 to 6.

FIG. 20 is a schematic diagram showing a portion of a cross-section of the electromagnetic wave attenuation film described in Example 7.

FIG. 21 is a schematic plan view showing a portion of the electromagnetic wave attenuation film described in Example 18.

FIG. 22 is a schematic diagram showing a portion of a cross-section taken along line I-I of the electromagnetic wave attenuation film described in Example 18.

FIG. 23 is a schematic diagram showing a portion of a cross-section taken along line III-III of the electromagnetic wave attenuation film described in Example 18.

FIG. 24 is a graph showing the electromagnetic wave attenuation characteristics of Example 1.

FIG. 25 is a graph showing the electromagnetic wave attenuation characteristics of Example 2.

FIG. 26 is a graph showing the electromagnetic wave attenuation characteristics of Example 3.

FIG. 27 is a graph showing the electromagnetic wave attenuation characteristics of Example 4.

FIG. 28 is a graph showing the electromagnetic wave attenuation characteristics of Example 5.

FIG. 29 is a graph showing the electromagnetic wave attenuation characteristics of Example 6.

FIG. 30 is a graph showing the electromagnetic wave attenuation characteristics of Example 7.

FIG. 31 is a graph showing the electromagnetic wave attenuation characteristics of Example 8.

FIG. 32 is a graph showing the electromagnetic wave attenuation characteristics of Example 9.

FIG. 33 is a graph showing the electromagnetic wave attenuation characteristics of Example 10.

FIG. 34 is a graph showing the electromagnetic wave attenuation characteristics of Example 11.

FIG. 35 is a graph showing the electromagnetic wave attenuation characteristics of Example 12.

FIG. 36 is a graph showing the electromagnetic wave attenuation characteristics of Example 13.

FIG. 37 is a graph showing the electromagnetic wave attenuation characteristics of Example 14.

FIG. 38 is a graph showing the electromagnetic wave attenuation characteristics of Example 15.

FIG. 39 is a graph showing the electromagnetic wave attenuation characteristics of Example 16.

FIG. 40 is a graph showing the electromagnetic wave attenuation characteristics of Example 17.

FIG. 41 is a graph showing the electromagnetic wave attenuation characteristics of Example 18.

FIG. 42 is a graph showing the electromagnetic wave attenuation characteristics of Example 12 and Example 13.

FIG. 43 is a graph showing the electromagnetic wave attenuation characteristics of Example 19.

FIG. 44 is a graph showing the electromagnetic wave attenuation characteristics of Reference Example 1.

FIG. 45 is a graph showing the electromagnetic wave attenuation characteristics of Reference Example 2 and Reference Example 3.

FIG. 46 is a schematic diagram showing a portion of a cross-section of the electromagnetic wave attenuation film of Comparative Example 1.

FIG. 47 is a graph showing the electromagnetic wave attenuation characteristics of Comparative Example 1.

FIG. 48 is a graph showing the electromagnetic wave attenuation characteristics of Comparative Example 2.

FIG. 49 is a graph showing the electromagnetic wave attenuation characteristics of Comparative Example 3.

### DETAILED DESCRIPTION

Hereinafter, embodiments of the present invention will be described with reference to the drawings. Note that the present invention is not limited to the embodiments. Furthermore, in the description of the drawings, like parts are indicated with like reference signs. In addition, the reference signs of like parts are sometimes omitted.

In the disclosure of the embodiments, the directions indicated as the x-axis, y-axis, and z-axis in the drawings may sometimes be used to describe directions. Also, unless otherwise specified, “plane” refers to the xy-plane, “planar view” refers to a view from the z-axis direction, “plan view” refers to the surface that is seen from the z-axis direction, and “planar view shape” and “planar shape” refer to the drawing shape viewed from the z-axis direction.

Moreover, in the disclosure of the embodiments, a “front surface” of an object refers to the surface that is seen when the object is viewed from the positive z-axis direction, a “back surface” refers to the surface that is seen when the object is viewed from the negative z-axis direction, and a “side surface” refers to an outer peripheral surface that is sandwiched by the front surface and the back surface. The “thickness direction” refers to the z-axis direction.

Furthermore, in the disclosure of the embodiments, “center of gravity” refers to the center of gravity of the planar shape.

### First Embodiment

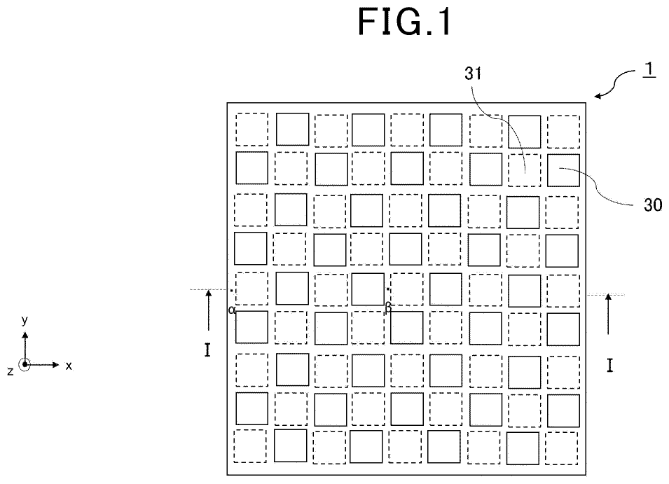

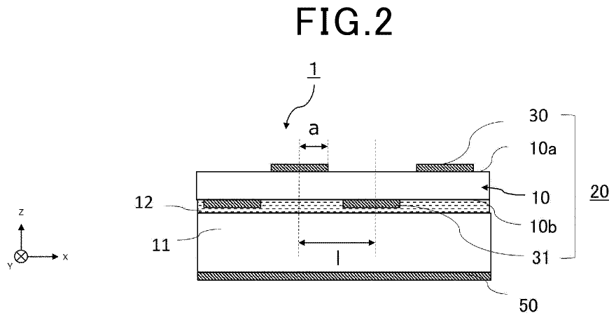

FIG. 1 is a schematic plan view showing an electromagnetic wave attenuation film 1 according to a first embodiment of the present invention. FIG. 2 is a schematic view showing a portion of a cross-section taken along line I-I in FIG. 1. For example, the cross-section is taken between α and β along line I-I.

The electromagnetic wave attenuation film 1 includes: an electromagnetic wave attenuation substrate 20 configured by a dielectric substrate (dielectric layer) 10, a thin film conductive layer 30 formed on a front surface 10a of the dielectric substrate 10, and a thin film conductive layer 31 formed on a back surface 10b of the dielectric substrate 10; a support layer 11 formed on a back surface of the thin film conductive layer 31, which is on the back surface; and a flat plate inductor 50 formed on a back surface of the support layer 11. The thin film conductive layers 30 and 31 are layers formed of a thin conductor body. The thin film conductive layers 30 and 31 may include a plurality of conductive elements (hereinafter, the thin film conductive layers may sometimes be referred to as conductive elements when specific shapes and arrangements are considered). The flat plate inductor 50 is conductive, and an electric current is generated inside the flat plate inductor 50 in the vicinity of the surface due to an external magnetic flux. Furthermore, as a result of the electric current, a function is provided in which a magnetic field is generated outside the flat plate inductor 50 in the vicinity of the surface. The shape of the flat plate inductor 50 can be a flat plate (slab). Note that the front surface can be the surface on the side that electromagnetic waves are incident. The back surface is the surface on the opposite side to the front surface of the dielectric substrate.

In addition, when an electromagnetic wave that is attenuated by the electromagnetic wave attenuation film has a frequency f at which the electromagnetic wave becomes a single minimum value, the frequency f is defined as an attenuation center frequency f. Also, when an electromagnetic wave that is attenuated by the electromagnetic wave attenuation film has a plurality of minimum values, the frequency obtained by taking the average of the plurality of frequencies at which electromagnetic wave becomes −3 dB from the minimum value, which represents the greatest attenuation, is used as the attenuation center frequency. The attenuation center wavelength can be obtained by dividing the light velocity in the dielectric substrate and the support layer by the attenuation center frequency f described below.

Moreover, the electromagnetic wave attenuation film 1 may also be provided with a top coat layer 200 (described below) for achieving impedance matching with air, and for improving the weather resistance of the sheet.

### (Electromagnetic Wave Attenuation Substrate)

As shown in FIG. 2, the electromagnetic wave attenuation substrate 20 has a configuration in which the thin film conductive layers 30 and 31 are arranged on the front surface 10a and the back surface 10b of the dielectric substrate 10.

A representative example of the material forming the dielectric substrate 10 is a synthetic resin. The type of synthetic resin is not particularly limited as long as it has insulation properties, as well as sufficient strength, flexibility, and processability. The synthetic resin can be a thermoplastic resin. Examples of the synthetic resin include, but are not limited to, polyesters such as polyethylene terephthalate (PET), polyarylene sulfides such as polyphenylene sulfide, polyolefins such as polyethylene and polypropylene, polyamides, polyimides, polyamideimides, polyethersulfones, polyetheretherketones, polycarbonates, acrylic resins, and polystyrene. These materials may be used alone, or two or more types may be mixed together or may be formed into a laminate. Furthermore, the dielectric substrate 10 may also contain conductive particles, insulating particles, magnetic particles, or a mixture thereof.

In order to form the electromagnetic wave attenuation substrate 20, a laminate in which the thin film conductive layers 30 and 31 are formed on both surfaces of the dielectric substrate 10 via an anchor layer or an adhesive layer may be used.

In addition, the dielectric substrate 10 has a bending rigidity of 7,000 MPa·mm⁴ or less.

In the embodiment of the present invention, the thickness of the dielectric substrate and the support layer can be made sufficiently thin with respect to the wavelength of the electromagnetic waves. It is known that when the dielectric substrate and the support layer are sufficiently thin with respect to the wavelength of the electromagnetic waves, no traveling waves are generated inside the dielectric substrate and the support layer. “Sufficiently thin” can be less than half the wavelength. Below half the wavelength, traveling waves are not guided. This is a phenomenon referred to as cutoff of an electromagnetic wave. The thickness can be one-tenth of the wavelength or less. Generally, when the difference in propagation distance of electromagnetic waves is one-tenth of the wavelength or less, a phase difference substantially does not occur. In other words, if the distance between the conductive elements and the flat plate inductor is one-tenth or less of the wavelength at the dielectric substrate and the support layer, because of the distance, a phase difference substantially does not occur between the electromagnetic waves re-emitted by the conductive elements and the reflected waves from the flat plate inductor. It is thought that electromagnetic waves are not guided within a sufficiently thin dielectric substrate and support layer that are sandwiched between conductive bodies, and at such a thickness, the electromagnetic waves are normally blocked (cut-off), and electric fields and magnetic fields do not localize at such a dielectric substrate and support layer. Note that, in the embodiment of the present invention, the wavelength can be the attenuation center wavelength. In addition, unexpectedly, attenuation is obtained even when the dielectric substrate and the support layer are less than one-hundredth of the wavelength. Such a thickness is the same level as the unevenness of a highest-precision mirror surface and indicates that attenuation is obtained with a structure that substantially does not have a thickness with respect to the scale of electromagnetic waves.

As a result of various experiments and simulations, the inventors have found that standing localization of an electric field and a magnetic field due to electromagnetic waves occurs even in a sufficiently thin dielectric substrate and support layer. Furthermore, because the magnitudes of the resonant frequency band and absorption amount change depending on the thickness of the support layer, it is necessary to accordingly change the design. The thickness of the dielectric substrate 10 can be 5 μm or more and 300 μm or less. In addition, the thickness of the dielectric substrate 10 can be 5 μm or more and 100 μm or less. This is less than half of the wavelength of a millimeter wave band, and further, is less than one-tenth of the wavelength of a millimeter wave band. Therefore, the electromagnetic wave attenuation film is capable of attenuating electromagnetic waves in the millimeter wave band despite being a thin film. The thickness of the dielectric substrate 10 may be fixed or variable. Similarly, the thickness of the support layer 11 can be 5 μm or more and 250 μm or less. In addition, the thickness can be 10 μm or more and 200 μm or less. Further, the thickness can be 15 μm or more and 150 μm or less.

In the embodiment of the present invention, the electromagnetic wave attenuation substrate 20 may be provided with a pressure-sensitive adhesive layer 12 between the dielectric substrate 10 and the support layer 11. The support layer 11 is single-layered or multi-layered. As the material of the support layer 11, the same materials as the dielectric substrate 10 can be used. For example, the resin can be a single resin, a mixture, or a composite of a urethane resin, an acrylic resin, a polyamide, a polyimide, a polyamideimide, an epoxy resin, or a silicone resin. The support layer 11 can be an extruded film. The extruded film can be an unstretched film or a stretched film. Furthermore, the support layer may be formed by being coated on the back surface of the electromagnetic wave attenuation substrate 20. The pressure-sensitive adhesive layer 12 may be configured by two layers, namely a forming layer and an anchor layer. Further, an adhesive layer may be provided in order to improve the adhesion between the pressure-sensitive adhesive layer 12 and the conductive elements. The pressure-sensitive adhesive layer 12, the forming layer, the anchor layer, and the adhesive layer may use the same materials as those constituting the dielectric substrate.

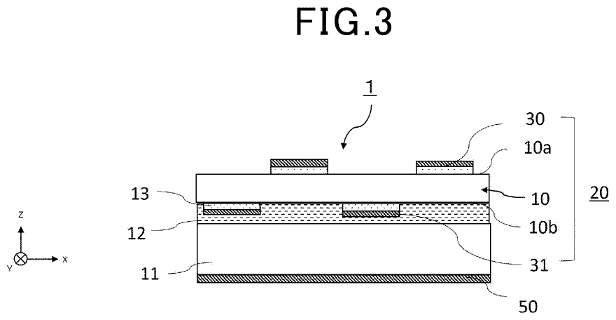

The thin film conductive layer 30 that is formed on the front surface 10a of the dielectric substrate 10, and the dielectric substrate 31 that is formed on the back surface 10b cover a portion or all of the front surface 10a and the back surface 10b of the electromagnetic wave attenuation film 1 in a planar view. As shown in FIG. 2, the thin film conductive layers 30 and 31 can be formed by a method in which layers are formed by directly vapor-depositing or sputtering a conductive material on both surfaces of the dielectric substrate 10, and then patterning the layers by etching or the like. FIG. 3 is a cross-sectional view of a case in which a thin film conductive layers are arranged and patterned on the dielectric body via pressure-sensitive adhesive layers. As shown in FIG. 3, the thin film conductive layers 30 and 31 can be formed by a method in which foils of a conductive material are attached to the dielectric substrate 10 via pressure-sensitive adhesive layers 13 to form the thin film conductive layers, and then arranging the conductive material as a result of patterning by etching or the like. As shown in FIG. 3, even in a case where conductive patterns are formed on the dielectric substrate 10 via the pressure-sensitive adhesive layers 13, because the pressure-sensitive adhesive layers 13 are patterned having the same dimensions as the conductive patterns, if a stress is applied by bending or the like of the electromagnetic wave attenuation film on which the conductive patterns have been formed on the dielectric substrate 10, because the stress is divided between each conductive pattern, an offset does not occur between the conductive patterns formed on the front surface and the back surface of the dielectric body.

The flat plate inductor 50 covers part or all of the back surface of the support layer 11. As long as the performance of the electromagnetic wave attenuation film 1 is not significantly impaired, for example, a part that is not covered by the thin film conductive layers 30 and 31 and the flat plate inductor 50 may exist on a portion of the peripheral edge or the like of the electromagnetic wave attenuation film 1.

The material of the thin film conductive layers 30 and 31 and the flat plate inductor 50 is not particularly limited as long as the material is conductive. From the viewpoint of corrosion resistance and cost, aluminum, copper, silver, gold, platinum, tin, nickel, cobalt, chromium, molybdenum, iron and alloys thereof are preferable. The thin film conductive layers 30 and 31 and the flat plate inductor 50 can be formed by performing vacuum vapor deposition on the dielectric substrate 10, and can also be formed by attaching foils of a conductive material to the dielectric substrate 10 via the pressure-sensitive adhesive layers 13. The film thickness of the pressure-sensitive adhesive layers 13, through which the foils of the conductive material are attached to the dielectric body, can be 10 nm or more and 2,000 nm or less. When the film thickness is less than 10 nm, there is a possibility that the adhesion of the foils of the conductive material to the dielectric body may decrease, and when the film thickness exceeds 2,000 nm, there is a possibility that the productivity may fall. In addition, the pressure-sensitive adhesive layer 13 has a bending rigidity of 7,000 MPa·mm⁴ or less. Further, the ratio of the film thicknesses of the thin film conductive layers 30 and 31 and the pressure-sensitive adhesive layers 13 is preferably 1:2.

The flat plate inductor 50 may be formed of a conductive compound. Also, the flat plate inductor 50 may be a continuous surface or may have a pattern such as a mesh shape or a patch.

The thickness of the thin film conductive layers and 30 and 31 can be 10 nm or more and 1,000 nm or less. When the thickness is less than 10 nm, there is a possibility that the function of attenuating electromagnetic waves may be reduced. When the thickness exceeds 1,000 nm, there is a possibility that the productivity may fall.

The flat plate inductor 50 can be a casting, a rolled metal plate, a metal foil, a vapor-deposited film, a sputtered film, or a plating. The thickness of the rolled metal plate can be 0.1 mm or more and 5 mm or less. The thickness of the metal foil can be 5 μm or more and less than 100 μm. When the flat plate inductor 50 is a vapor-deposited film, a sputtered film, or a plated film, the thickness can be 0.5 μm or more and less than 5 mm. The thickness of the flat plate inductor 50 can be 0.5 μm to 5 mm. Furthermore, when the flat plate inductor 50 is a casting, although the thickness is not limited, the maximum dimension can be 10 mm or more. In addition, the thickness of the flat plate inductor 50 is greater than or equal to a skin depth determined by the attenuation center wavelength. Also, the thickness of the flat plate inductor 50 can be made thicker than the thickness of the thin film conductive layers 30 and 31.

The material of the thin film conductive layers 30 and 31 and the flat plate inductor 50 can be the same type of metal. This same type of metal may be the same pure metal or the same metal alloy (for example, both are an aluminum alloy), or the thin film conductive layers 30 and 31 may be a pure metal and the flat plate inductor 50 may be an alloy of the metal of the thin film conductive layer 30. Furthermore, the material of the thin film conductive layers 30 and 31 and the flat plate inductor 50 can be different types of metals.

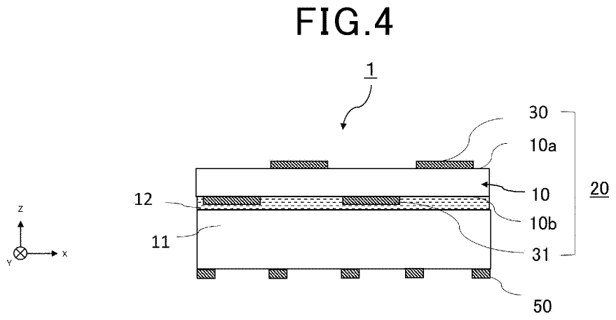

FIG. 4 is a cross-sectional view of a case where a flat plate inductor is formed having a mesh shape. When the flat plate inductor 50 is formed having a mesh shape, it is thought that light transmittance and moisture permeability are obtained. As a result of having moisture permeability, it is thought that benefits such as a high moisture permeability and ease of handling are obtained, for example, when an environmentally friendly, water-based pressure-sensitive adhesive agent is used as the pressure-sensitive adhesive agent at the time of attachment to a wallpaper or the like.

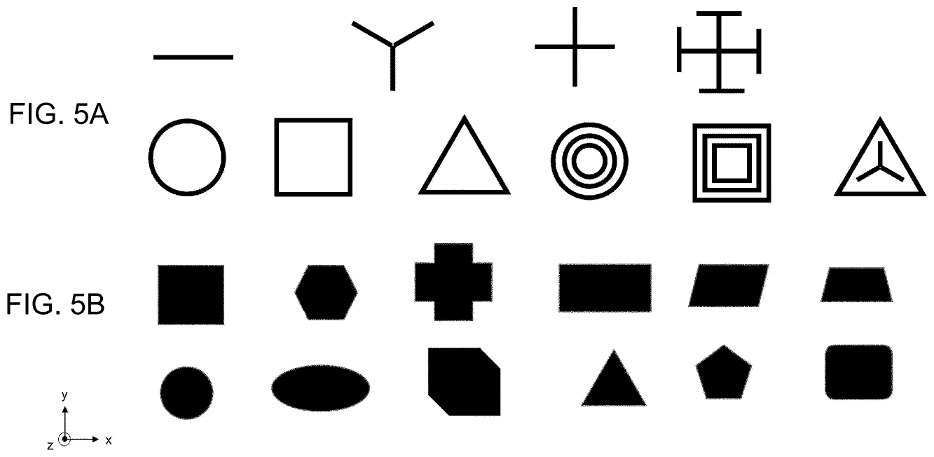

The shapes and combinations of shapes of the conductive elements 30 and 31 will now be described. FIGS. 5A and 5B are schematic views showing examples of planar view shapes of a conductive element. Examples include the line shapes shown in FIG. 5A and the plane shapes shown in FIG. 5B. The line shapes include open-ended shapes consisting of a straight line, a Y-shape, a cross, and a combination of these shapes, and loop shapes such as a circle, an ellipse, and a polygon. The plane shapes include polygonal shapes such as a square shape, a hexagonal shape, a cross, other polygonal shapes, circles, and ellipses. The corners of the square shape, hexagonal shape, cross, and other polygonal shapes may have a rounded shape, but it is not limited to this.

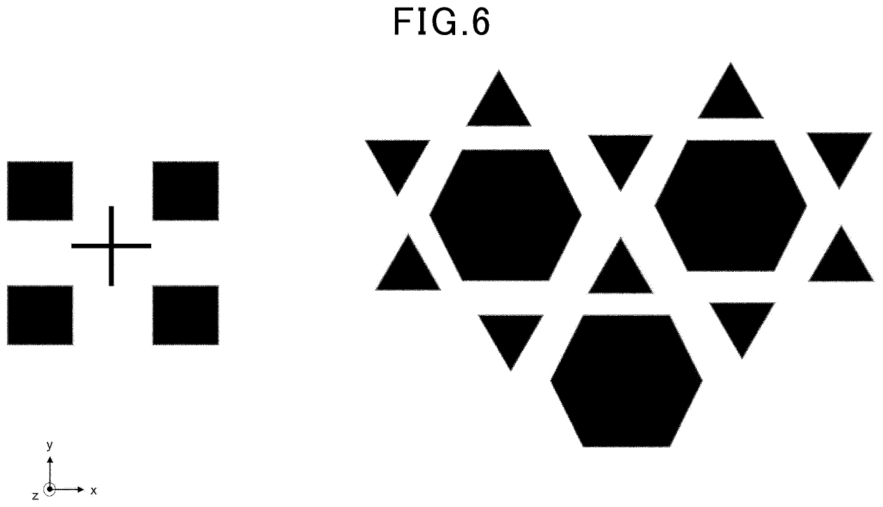

Furthermore, FIG. 6 is a schematic view showing examples of combinations of planar view shapes of a conductive element. The combinations may consist of shapes having different sizes and may also be combinations of single shapes or a plurality of shapes.

As a result of the configuration described above, the electromagnetic wave attenuation film 1 is considered to exhibit a unique mechanism at specific wavelengths.

An electromagnetic wave that is incident to the electromagnetic wave attenuation film of the present invention behaves as follows. Specifically, the electromagnetic field and current generated by an incident wave are considered to be as follows.

First, a fluctuation of the magnetic flux of an incident wave transmitted through the conductive elements induces an AC current in the flat plate inductor 50 that is parallel to the incident plane of the flat plate inductor 50 according to Faraday's law. The AC current generates a fluctuating magnetic field in the dielectric substrate adjacent to the flat plate inductor 50 according to Ampere's law. Furthermore, the fluctuating magnetic field becomes a magnetic flux that fluctuates with the magnetic permeability as a coefficient.

The electric field generated by a fluctuating magnetic flux will normally induce a current in a direction that suppresses the magnetic flux according to Henry's law. However, in the case of the configuration of the present application, contrary to expectation, the effect acts in the opposite direction, and increases the current. This causes a current to flow in the conductive element which is at least the current induced by the incident wave. That is, although the area of the conductive element is smaller than the area of the flat plate inductor 50, it is possible to generate about the same current as in the flat plate inductor 50.

The direction of the current generated in the conductive elements is in the opposite direction to that of the flat plate inductor 50. A closed circuit can be formed by the currents flowing in opposite directions through the conductive elements and the flat plate inductor 50 and a displacement current flowing therebetween. If a closed circuit is formed only between the conductive elements and the flat plate inductor 50, and an electric flux is not generated in the space outside the electromagnetic wave attenuation film that is parallel to the electromagnetic wave attenuation film, a reflected wave cannot be generated. In addition, the reflected wave from the flat plate inductor 50 and the electromagnetic wave that is re-emitted by the current of the conductive elements are out of phase with each other by π, so they cancel each other out.

As a result of the above principle, the reflected wave is attenuated by the electromagnetic wave attenuation film. From the viewpoint of energy, a plurality of mechanisms are considered to be acting synergistically as follows.

The first mechanism is the generation of a non-traveling, periodically oscillating electromagnetic field by an incident wave. First, the flat plate inductor 50 causes a magnetic flux to be induced by the incident wave in a tangential direction to the flat plate inductor 50. The induced magnetic flux generates an electric field in a direction perpendicular to the flat plate inductor 50 in a direction extending from a pair of opposing sides of the thin film conductive layers 30 and 31 (that is, the conductive elements). Next, when the electromagnetic wave is incident to the flat plate inductor, a current is induced so as to be in close proximity to the surface of the flat plate inductor due to the fluctuating magnetic flux. As a result of the current induced inside the flat plate inductor, a magnetic field is generated in the dielectric substrate 10 and the support layer 11 in close proximity to the surface of the flat plate inductor. The electric field and the current of the conductive elements and the flat plate inductor 50 generate a magnetic field between the conductive elements and the flat plate inductor 50 having the same orientation as the magnetic flux induced by the flat plate inductor 50. Here, the conductive elements have a plate shape and are made of a metal material. The electric field generated inside the dielectric substrate fluctuates with the same period as the period of the incident wave. The periodic fluctuations in the magnetic field cause the electric field between the thin film conductive layers 30 and 31 and the flat plate inductor 50 to periodically fluctuate. As a result, a non-traveling, periodically fluctuating electromagnetic field is generated between the thin film conductive layers 30 and 31 and the flat plate inductor 50. As will be shown later by a simulation of the current density, the magnetic field of the periodically fluctuating electromagnetic field induces an AC current in the conductive elements. Furthermore, the periodically fluctuating electric field induces a periodically fluctuating electric potential in the conductive elements. The electromagnetic field does not travel and remains stationary, the induced AC current loses power, and as a result, the energy of the electromagnetic field is converted into heat, which absorbs the electromagnetic wave. It is also thought that the AC current induced in the conductive elements re-emits the electromagnetic wave from the surface of the conductive elements on the opposite side to the surface in contact with the dielectric substrate 10 and the support layer 11.

That is, it is thought that a portion of the energy of the electromagnetic wave captured by the electromagnetic wave attenuation film is converted into thermal energy, and the remainder is re-emitted. Furthermore, according to classical electromagnetic theory represented by Maxwell's equations and the like, because the frequency of the induced AC current is the same as that of the incident wave, the frequency of the re-emitted electromagnetic wave is the same as that of the incident wave. As a result, an electromagnetic wave having the same frequency as the incident wave is re-emitted. In addition, when an oscillating electromagnetic field is considered to be a quantum, it is possible that the quantum can lose energy, resulting in re-emission of a lower-energy, longer-wavelength electromagnetic wave. Furthermore, the re-emission is thought to include induced emission due to the incident electromagnetic wave, and spontaneous emission. An induced emission is considered to be the emission of an electromagnetic wave that is coherent with the reflected wave, in which the incident wave is reflected in the reflection direction of the incident wave, that is, in a mirror reflection direction. A spontaneous emission is considered to decay with time. Furthermore, the spatial distribution of a spontaneous emission is considered to be close to Lambertian reflection if the electromagnetic wave attenuation film does not have a diffractive structure, an interference structure, or a refractive structure.

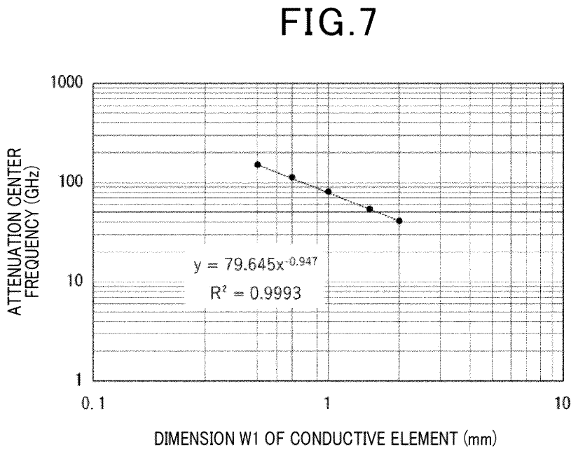

The attenuation center wavelength is correlated to a dimension W1 in the surface direction of the conductive elements 30 and 31 (see FIG. 7, sometimes referred to as “width W1” below). FIG. 7 is a graph showing the relationship between the dimensions of a conductive element and the wavelength of attenuated electromagnetic waves. In FIG. 7, W1 represents the length of one side of a square shape. That is, the wavelength of an electromagnetic wave that is more preferably attenuated by the first mechanism can be changed by changing the dimension W1, and in the electromagnetic wave attenuation film 1, the attenuation of an electromagnetic wave can be easily set with a high degree of freedom. Therefore, a configuration can be easily achieved that is capable of capturing linearly polarized electromagnetic waves in a band of 15 GHz or more and 150 GHz or less.

The periodic fluctuation of a non-traveling electromagnetic field is considered to occur between opposite sides of the conductive elements in a planar view. Therefore, in order for the first mechanism to occur, it is preferable that sides of a fixed length are facing each other. Given this and the results of the investigations by the inventors, sections of the thin film conductive layer having a width W1 of 0.25 mm or more can serve as the conductive elements. When a certain conductive element may take a plurality of W1 values, the maximum value among them can be defined as the W1 value of the conductive element. As a result of setting W1 in a range of approximately 0.25 mm to 4 mm, it becomes possible to attenuate electromagnetic waves in a band of 15 GHz or more and 150 GHz or less. As shown in FIG. 7, the relationship between the frequency of the attenuated electromagnetic waves and the width of the conductive elements can be expressed as a straight line on a graph in which each value is expressed logarithmically. That is, the frequency of the attenuated electromagnetic waves is a power function of the width of the conductive elements. The power of the function is approximately −1 and is substantially inversely proportional.

The thin film conductive layer may include a plurality of types of conductive elements having different dimensions W1. In this case, each of the electromagnetic wave attenuation peaks are overlapped, and the band of the electromagnetic waves that can be attenuated can be broadened.

The second mechanism is the confinement of the electromagnetic field by the thin film conductive layers 30 and 31 and the flat plate inductor 50. In the electromagnetic wave attenuation film 1, the dielectric substrate 10 and the support layer 11 are sandwiched by the thin film conductive layers 30 and 31 and the flat plate inductor 50. As a result, the electric field generated in the dielectric substrate 10 and the support layer 11 of the electromagnetic wave attenuation film 1 by the electromagnetic wave is confined within the dielectric substrate 10 and support layer 11 between the thin film conductive layers 30 and 31, which include the conductive elements and the flat plate inductor 50 by the charge and current of the conductive elements. Therefore, the conductive elements suppress the electromagnetic field and confine the electromagnetic field to the dielectric substrate 10 and the support layer 11. That is, the conductive elements can function as a choke. In other words, the conductive elements can serve as a choke plate that functions as a choke.

Furthermore, the magnetic flux is also considered to be induced by the periodic fluctuations of the confined electric field. This causes the oscillating electromagnetic field to concentrate, increasing the energy density of the electromagnetic field. Generally, the attenuation becomes easier as the energy density increases, and therefore, an electromagnetic wave is efficiently attenuated by this mechanism. Also, in the second mechanism, the energy loss of the electromagnetic field that has accumulated inside the dielectric substrate increases as the dielectric loss tangent of the dielectric substrate 10 and the support layer 11 increases. In addition, the magnetic field that has concentrated in the dielectric substrate results in a large current in the conductive elements, and the electric field that has concentrated in the dielectric substrate results in a large potential difference. A large current and a large potential difference can increase the power loss, which is the product of the two values. As a result of the power loss, the energy of the electromagnetic wave is consumed, resulting in an attenuation of the electromagnetic wave.

The third mechanism is due to a power loss in an electric circuit including the opposing thin film conductive layers 30 and 31 and the flat plate inductor 50, and a capacitor formed by the dielectric substrate 10 and the support layer 11 arranged therebetween. In the electromagnetic wave attenuation film 1, the dielectric substrate 10 and the support layer 11 are sandwiched by the thin film conductive layers 30 and 31 and the flat plate inductor 50. As a result, the dielectric substrate 10 and the support layer 11 function as a capacitor. Therefore, an electromagnetic wave that is incident to the dielectric substrate 10 and the support layer 11 of the electromagnetic wave attenuation film 1 is attenuated by the electric circuit including the capacitor. As the capacitance of the capacitor increases, more charge can be accumulated and the energy that can be stored increases, and therefore, a larger capacitance enables handling of more energy.

Because the capacitance is inversely proportional to the thickness of the dielectric substrate 10 and the support layer 11, from this perspective, it is preferable that the thickness of the dielectric substrate 10 and the support layer 11 is small. Furthermore, because the distance between the thin film conductive layers 30 and 31 and the flat plate inductor 50 is determined by the thickness of the dielectric substrate 10 and the support layer 11, the electrical resistance between the thin film conductive layers 30 and 31 and the flat plate inductor 50 is proportional to the thickness of the dielectric substrate 10 and the support layer 11. When the resistance of the dielectric substrate 10 and the support layer 11 is small, the leakage current in the dielectric substrate 10 and the support layer 11 increases, and the current that flows in the electric circuit including the capacitor formed by the thin film conductive layer 30 and the flat plate inductor 50 increases. This tends to increase the power loss due to the leakage current, and the power loss tends to absorb the energy of the electromagnetic wave. Furthermore, in the electromagnetic wave attenuation film 1 according to the embodiment of the present invention, because the wavelength of the attenuated electromagnetic field does not shift even if the thickness of the dielectric substrate 10 and the support layer 11 is changed at the locations in which the conductive elements are arranged, the thickness of the dielectric substrate 10 and the support layer 11 can be designed according to the characteristics of the electric circuit including the capacitor.

As described above, an electromagnetic wave that is incident to the electromagnetic wave attenuation film 1 is captured by causing an electromagnetic field to be generated in the dielectric substrate 10 and the support layer 11 in close proximity to the surface of the flat plate inductor due to the first mechanism, and confining the electromagnetic field that has been generated by the electromagnetic wave due to the second mechanism. In this way, the electromagnetic wave attenuation film 1 is capable of capturing the electromagnetic wave. The captured electromagnetic wave is attenuated by the electric field loss and the power loss due to the second mechanism, and the power loss by the electric circuit due to the third mechanism.

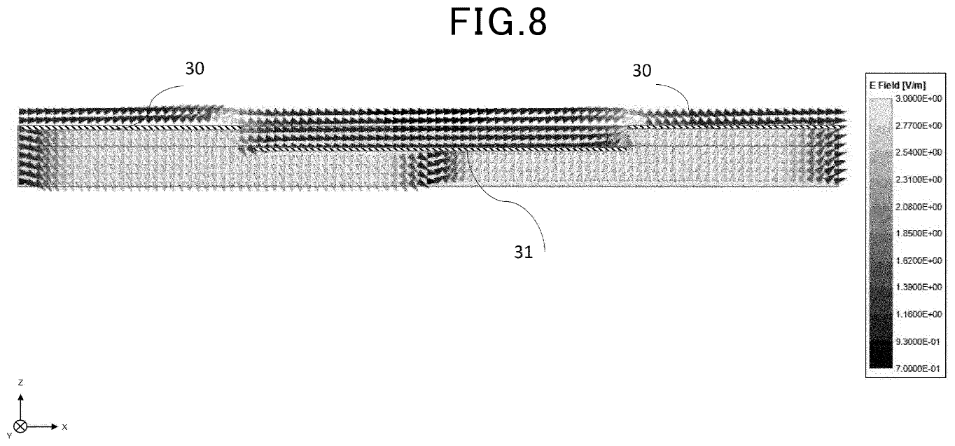

In the electromagnetic wave attenuation film 1 of the first embodiment, as shown in FIG. 2, the thin film conductive layer 30 that is formed on the front surface 10a of the dielectric substrate 10, and the dielectric substrate 31 that is formed on the back surface 10b include conductive elements. When the distance between the center of gravity of the conductive elements arranged on the front surface 10a of the dielectric substrate 10 and the center of gravity of the conductive elements arranged on the back surface 10b in the same plane is 1, and the shortest distance from the center of gravity of the conductive elements to the plate end portion is a, by arranging the conductive elements in positions that satisfy equation (1) below, it becomes possible to create an absorber in which attenuation at a target frequency can be obtained. FIG. 8 is an image showing a simulation result of the electric field intensity for one example of a distance between the conductive elements on the front surface and the conductive elements on the back surface. When the distance 1 is arranged to be 2a, which is a position that satisfies equation (1) below, it can be understood that when an electromagnetic wave is incident from the front surface, as shown in FIG. 8, resonant coupling is observed between the conductive elements 30 on the front surface and the conductive elements 31 on the back surface, which generates a strong electric field. This makes it possible to efficiently attenuate the electromagnetic wave.

$$I ≦ 5.2 a \qquad ( 1 )$$

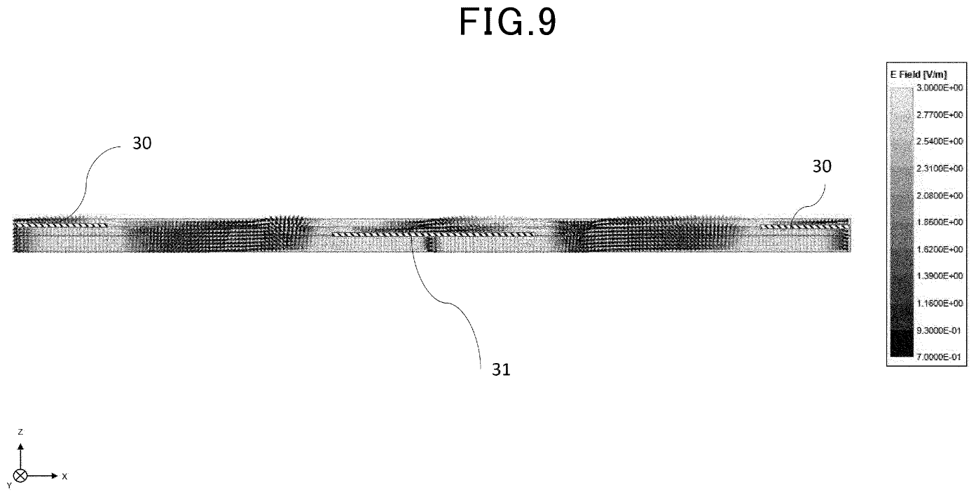

FIG. 9 is an image showing a simulation result of the electric field intensity for another example of a distance between the conductive elements on the front surface and the conductive elements on the back surface. When the conductive elements are arranged with 1 as 5a, which is greater than 4a, although it is possible to attenuate an electromagnetic wave, as shown in FIG. 9, the conductive elements on the front surface and the conductive elements on the back surface resonate independently such that the resonance of the conductive elements on the front surface and the back surface is no longer coupled, and the effect of arranging the conductive elements on the front surface and the back surface is reduced. Further, when 1 is greater than or equal to 5.2a, and the conductive elements on the front surface and the back surface are separated by a large distance, it becomes difficult to attenuate an electromagnetic wave in a target frequency.

In the electromagnetic wave attenuation film 1, the role played by the third mechanism is also important. When an electromagnetic wave is incident to the front surface 10a of the dielectric substrate 10 and an electric field is generated in the dielectric substrate 10, an electric field is also generated in the support layer 11 arranged between the back surface 10b and the flat plate inductor 50, and an electromagnetic field is confined below the conductive elements. That is, an electromagnetic field having a high energy density is generated below the conductive elements. The confined electromagnetic field is considered to be attenuated by the power loss due to the second mechanism, and by the dielectric loss due to the third mechanism.

### First Embodiment (Application)

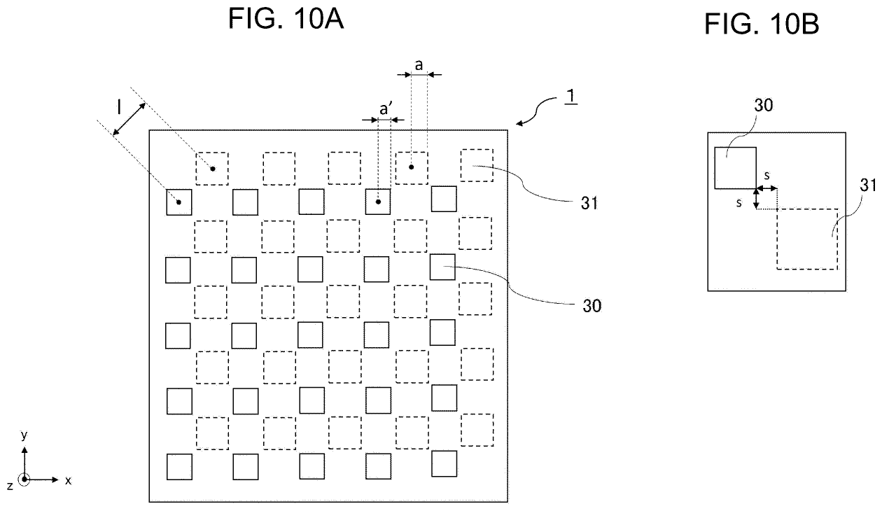

FIGS. 10A and 10B are a schematic plan view showing an electromagnetic wave attenuation film according to an applied mode of the first embodiment of the present invention. FIG. 10A is an overall plan view, and FIG. 10B is a partial plan view. In the present applied mode, the plurality conductive elements 30 on the front surface and the conductive elements 31 on the back surface are arranged in a checkerboard pattern, and the conductive elements on the front surface and the back surface are designed having different sizes. FIG. 10A shows the distance 1 between the center of gravity of the conductive elements on the front surface and the back surface in the plane direction, and the shortest distances a and a′ from the center of gravity of the conductive elements on the back surface or the front surface to the plate end portion. When referring to the size of the conductive elements on the back surface (or the conductive elements on the front surface) in FIG. 10A, it is possible to use a (or a′) as a representative parameter, but it is not limited to this, and for example, the area may be used. Furthermore, in the present applied mode, the conductive elements on the front surface or back surface may be arranged such that the largest value among the shortest distances from the center of gravity to the plate end portion satisfies equation (1). FIG. 10B shows a space (s) between the conductive elements on the front surface and the back surface. The other configurations are the same as those of the first embodiment, and the description will be omitted.

In the present applied mode, based on a phenomenon in which the conductive elements on the front surface and the conductive elements on the back surface resonate at their respective frequencies, it is possible to obtain a dual-band electromagnetic wave attenuation film using absorption peak frequencies that are different from each other. In addition, in the present applied mode described below, it has been found that when the dual-band absorption peak frequencies are separated by a predetermined spacing, there is a tendency for good attenuation characteristics to be obtained by designing the size (a′) of the conductive elements on the front surface to be smaller than the size (a) of the conductive elements on the back surface. As a preferable example, in a dual-band with absorption peak frequencies with a frequency spacing of at least a 28 GHz band and a 39 GHz band, good attenuation characteristics are obtained when the size of the conductive elements on the front surface are smaller than the size of the conductive elements on the back surface. Specifically, the tendency described above is expected to be observed in a dual band having absorption peak frequencies separated by at least the frequency interval between 29.5 GHz, which is the upper limit of the 28 GHz band, and 34 GHz, which is the lower limit of the 39 GHz band.

When the larger-sized conductive elements are formed on the front surface to which electromagnetic waves are incident, resonance contributes to the attenuation of low-frequency electromagnetic waves, but on the other hand, impedance matching cannot be achieved for high-frequency electromagnetic waves and results in an increase in reflections as a reflection plate, which is thought to be a factor that results in a deterioration of the attenuation characteristics. On the other hand, when dual-band absorption peak frequencies approach each other, no significant difference was observed in the attenuation characteristics due to a difference in the size relationship between the conductive elements on the front surface and the back surface. Note that arranging the conductive elements on the front surface and the back surface in a checkerboard pattern reduces coupling between frequencies and makes it easier to control the resonant frequency of each conductive element, which is desirable in terms of enhancing the dual-band characteristics, but the arrangement is not limited to such an arrangement.

In the conventional technique, it was believed that by making a resonating conductor thicker than the skin depth, a sufficient AC current is generated in the resonating layer, and the power loss of the AC current attenuates the electromagnetic wave. However, the inventors have found that when the thickness of the conductive elements becomes less than or equal to the skin depth, attenuation of the electromagnetic wave actually increases.

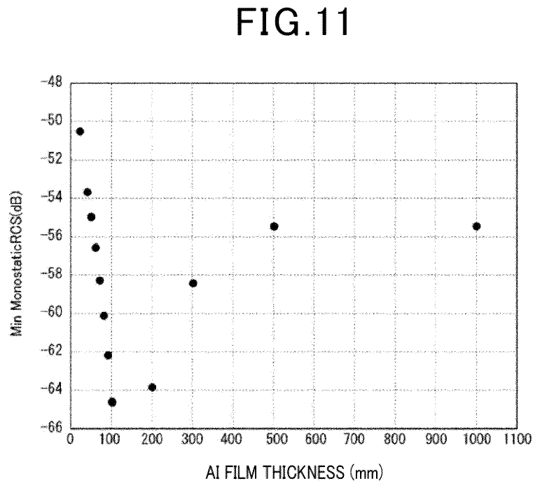

FIG. 11 is a graph showing a simulation result of the attenuation properties of an electromagnetic wave depending on variations in the thickness of a conductive element. The material of the conductive elements was aluminum. The incident wave was a sinusoidal linearly polarized wave, which was incident perpendicularly to the electromagnetic wave attenuation film. Note that, in the simulation, the flat plate inductor was treated as a perfect conductor. In terms of the electromagnetic wave attenuation properties as an electromagnetic wave attenuation film, a monostatic RCS, which was based on the flat plate inductor alone, was used as an index. Note that the vertical axis showing the electromagnetic wave attenuation properties is expressed in decibels. Monostatic RCS (radar cross-section) is an index that represents the ease of detection of a target by a monostatic radar, and can be calculated using the following equation. Note that a monostatic radar transmits and receives signals at the same location.

$$σ = {lim}_{R \to ∞} 4 π {R}^{2} \frac{{\vert {E}_{r} \vert}^{2}}{{\vert {E}_{i} \vert}^{2}} \qquad [ Math . 1 ]$$

Where
   |Er|: Incident electric field strength
   |Ei|: Received scattered electric field strength
R: Distance between target and radar

As a result of the simulation, as shown in FIG. 11, a large attenuation of the electromagnetic wave was observed when the thickness was 40 nm or more and 400 nm or less. Conversely, below 40 nm, a decrease in the attenuation of the electromagnetic wave was observed.

In addition, when the conductive elements are provided with a blackening layer, stable film formation is possible as long as the combined thickness of the conductive elements and the blackening layer is 1,000 nm or less.

The phenomenon shown in FIG. 11 has an interesting relationship with respect to the skin depth. The skin depth of aluminum at a frequency of 41 GHz is approximately 400 nm. That is, when the thickness of the conductive elements becomes less than or equal to the skin depth of the material, attenuation of the electromagnetic wave increases. Furthermore, at less than a skin depth of 1/e2, attenuation of the electromagnetic wave decreases. This is considered to be because, when the conductive layer is thicker than the skin depth, a sufficient resistance is not obtained and the voltage drop required for the power loss is not obtained, and further, the current is concentrated only near the center of the conductive elements, reducing the current in the regions where a potential difference is generated. On the other hand, even if the thickness of the conductive layer is less than or equal to the skin depth, at less than a skin depth of 1/e2, it is plausible that a sufficient current for the power loss is not obtained. Needless to say, the power loss is given by the product of the current and voltage. That is, it can be said that sufficient attenuation of an electromagnetic wave can be obtained as long as the following LN function in equation (2), which is expressed using the natural logarithm of a value obtained by normalizing the thickness T of the conductive elements by the skin depth d, is satisfied.

$$- 2 ≦ ln ( T / d ) ≦ 0 \qquad ( 2 )$$

Furthermore, when a metal with low admittance is used for the conductive elements, attenuation of an electromagnetic wave can be obtained even within the range of the following equation (3). In addition, when the area of the conductive elements occupies a large proportion of the front surface of the dielectric substrate, attenuation of an electromagnetic wave can be obtained even within the range of the following equation (3). When the area ratio is large, the proportion the area of the conductive elements occupies on the front surface of the dielectric substrate can be 50% or more and 90% or less.

$$0 ≦ ln ( T / d ) ≦ 1 \qquad ( 3 )$$

Given equations (2) and (3), the attenuation of an electromagnetic wave can be obtained within the range of the following equation (4).

$$- 2 ≦ ln ( T / d ) ≦ 1 \qquad ( 4 )$$

In the embodiment of the present invention, the skin depth can be calculated using the attenuation center frequency f. In other words, when the attenuation center frequency f is used, the skin depth d is calculated as shown in the following equation (5), as is well known.

$$\begin{matrix}[ Math . 2 ] & \\ d = \sqrt{\frac{2 ρ}{ωμ}} & ( 5 )\end{matrix}$$

Where
ρ=electrical resistivity of metal plate
ω=angular frequency of current=2π×attenuation center frequency f
μ=absolute magnetic permeability of metal plate

Furthermore, in the simulation results, the attenuation increased when the thickness of the conductive elements was less than the skin depth. This is thought to be because the current generated due to the influence of the magnetic flux of the dielectric substrate of the conductive elements reaches the surface on the opposite side of the dielectric substrate, and the current causes an electromagnetic wave whose phase is shifted by π from the wave reflected by the planar inductor to be emitted, which cancels out the wave reflected by the flat plate inductor. In addition, as the thickness of the conductive elements becomes thinner than the skin depth, the current in the conductive elements is restricted, resulting in a magnetic field being generated not only near the center of the conductive elements but in all areas of the conductive elements, and the current induced by the generated magnetic field also occurs in all areas of the conductive element, increasing the emission of the electromagnetic wave that cancels out the reflected wave from the flat plate inductor, which is considered to further attenuate the reflected wave.

Also, the electric field of the dielectric substrate between the conductive elements and the flat plate inductor attracts the conductive elements and the flat plate inductor. If the electric field is periodically fluctuating, the attractive force toward the conductive elements also periodically fluctuates. Therefore, the electric field of the dielectric substrate between the conductive elements and the flat plate inductor causes the conductive elements to vibrate. The energy of the vibrations is converted into heat and is lost. For this reason, it is thought that the dynamics of the electromagnetic field acting on the conductive elements also contributes to the attenuation of an electromagnetic wave.

Furthermore, if the non-traveling periodic fluctuations of an electromagnetic field are interpreted as a quantum, the quantum can be considered to be bound by the electromagnetic field and captured in a state in which the momentum is zero. In addition, because the thickness of the conductive elements is on the order of several hundred nm, there is a possibility that the energy levels within the conductive element may be affected.

In this way, the phenomenon described in the embodiment of the present invention can be interpreted not only as a classical electromagnetic phenomenon, but also as a classical mechanical or quantum mechanical phenomenon.

Consequently, when interpreting formula (4), the range is reasonably defined, but is not a range that has been strictly calculated taking into account all physical phenomena. Therefore, when determining whether a given product falls within the scope of the above equations, it is appropriate to consider and interpret the physical phenomena that are being exhibited.

Note that, in the conventional technique, examples of using a conductor having a thickness that is approximately equal to the skin depth or thinner than the skin depth are usually not observed. As a result, it is thought that the embodiment of the present invention has a different mechanism of interaction with electromagnetic waves in the millimeter wave band compared to the conventional technique.

### Second Embodiment

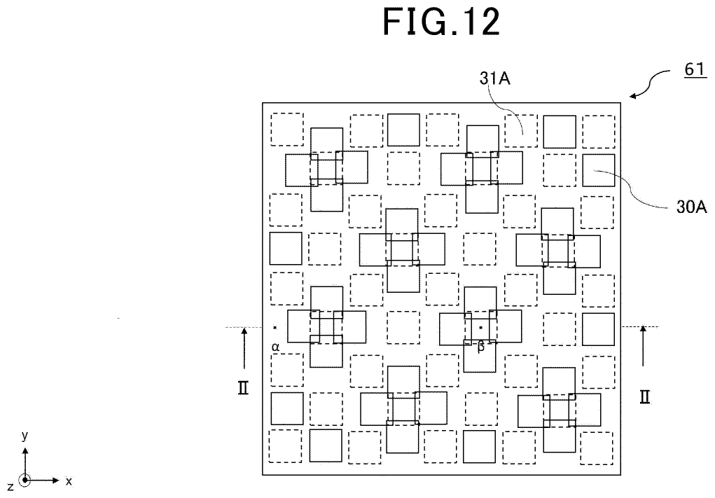

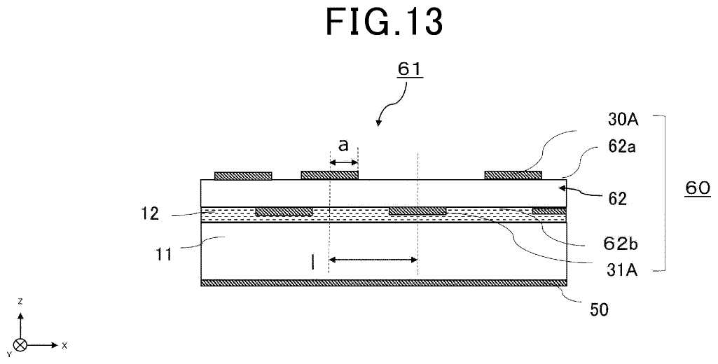

A second embodiment of the present invention will be described with reference to FIGS. 12 and 13. The second embodiment differs from the first embodiment in the arrangement of the conductive elements. In the following description, configurations that are common to those already described are denoted by the same reference signs, and duplicated descriptions will sometimes be omitted. In the second embodiment, each of the first, second, and third mechanisms described above are thought to be exhibited.

FIG. 12 is a schematic plan view showing an electromagnetic wave attenuation film according to the second embodiment of the present invention. FIG. 13 is a schematic view showing a portion of a cross-section taken along line II-II in FIG. 12. For example, the cross-section is taken between α and β along line II-II.

The electromagnetic wave attenuation film 61 includes a dielectric substrate 62, a plurality of conductive elements 30A and 31A, and a flat plate inductor 50. The thickness of the conductive elements 30A and 31A can be 1,000 nm or less.

The dielectric substrate 62 according to the second embodiment can be obtained using the same materials and configurations as the dielectric substrate 10 according to the first embodiment. As shown in FIG. 13, the electromagnetic wave attenuation substrate 60 has a configuration in which the thin film conductive layers 30A and 31A are arranged on a front surface 62a and a back surface 62b of the dielectric substrate 62. In order to form the electromagnetic wave attenuation substrate 60, a laminate in which the thin film conductive layers are formed on both surfaces of the dielectric substrate 62 via an anchor layer or an adhesive layer may be used.

The support layer 11 can be an extruded film. The extruded film can be an unstretched film or a stretched film. Furthermore, a support layer may be formed by being coated on the back surface of the electromagnetic wave attenuation substrate 60. The support layer has a bending rigidity of 7,000 MPa·mm⁴ or less.

The thin film conductive layer 30A that is formed on the front surface 62a of the dielectric substrate 62, and the dielectric substrate 31A that is formed on the back surface 62b cover a portion or all of the front surface 62a and the back surface 62b of the electromagnetic wave attenuation film 61 in a planar view. The flat plate inductor 50 covers part or all of the back surface 62b. As long as the performance of the electromagnetic wave attenuation film 61 is not significantly impaired, the flat plate inductor 50 may have, for example, a part that is not covered by the thin film conductive layers 30A and 31A and the flat plate inductor 50 that exists as a portion of the peripheral edge or the like of the electromagnetic wave attenuation film 61.

Although the flat plate inductor 50 is provided on the back surface of the support layer 11, an adhesive layer may be provided between the back surface of the support layer 11 and the flat plate inductor 50. The adhesive layer and the flat plate inductor 50 may be formed using the same materials and production methods as in the first embodiment.

The attenuation properties of the electromagnetic wave attenuation film 61 according to the second embodiment can be set by controlling the arrangement position of the conductive elements 30A and 31A that are arranged on the front surface 62a and the back surface 62b of the dielectric substrate 62. When the distance in a plane direction between the center of gravity of the conductive elements on the front surface and the back surface is 1, and the shortest distance from the center of gravity of the conductive elements to the plate end portion is a, it is possible to prepare the electromagnetic wave attenuation film 61 to exhibit electromagnetic wave attenuation performance at multiple frequencies as a result of mixing a combination of conductive elements on the front surface and the back surface satisfying equation (6) below, and a combination of conductive elements on the front surface and the back surface satisfying equation (7) below. Although the ranges of the combinations are not particularly limited, for example, in a planar view of the electromagnetic wave attenuation film, the combinations may be formed between conductive elements on the back surface (front surface) that are adjacent to predetermined conductive elements on the front surface (back surface).

When the relationship between the distance 1 in a plane direction between the center of gravity of the conductive elements on the front surface and the back surface and the shortest distance a from the center of gravity of the conductive elements to the plate end portion satisfy equation (6) below, the conductive elements on the front surface and the back surface overlap in the plane direction, the capacitance C represented by equation (8) below increases, and the resonant frequency shifts to a low frequency range. As a result of forming, on a single plane, a mixture of positions in which the conductive elements on the front surface and the back surface are arranged overlapping in the plane direction, and positions in which the conductive elements are not overlapping, it is possible to prepare the electromagnetic wave attenuation film to exhibit attenuation at multiple frequencies without changing the dimensions of the conductive elements.

$$I < 2 a \qquad ( 6 )$$

$$I ≧ 2 a \qquad ( 7 )$$

$$ω 0 = 1 / sqrt ( L C ) \qquad ( 8 )$$

w0: resonant frequency
L: reactance
C: capacitance

Further, by adjusting the ratio at which, on a single plane, the combinations in which the conductive elements on the front surface and the back surface are arranged overlapping in the plane direction, and the combinations in which the conductive element are not overlapping are mixed, and the area ratio of the overlap between the conductive elements on the front surface and the back surface in the plane direction, it is possible to control the frequency at which electromagnetic waves are attenuated, to attenuate electromagnetic waves over a broader band, and to prepare the electromagnetic wave attenuation film to have an attenuation peak that attenuates only a specific frequency among a plurality of frequencies. Although the calculation method of the mixture ratio is not particularly limited, for example, it is possible to calculate the mixture ratio from a ratio of the number of combinations that satisfy equation (6) to the number of combinations that satisfy equation (7). Note that, as shown in FIG. 12, although adjacent conductive elements on the front surface or adjacent conductive elements on the back surface may overlap each other, such conductive elements may be treated as being independent in the calculation of the combinations.

### <Blackening Layer>

In the embodiment of the present invention, blackening layers may be provided by performing blackening treatment around the thin film conductive layer.

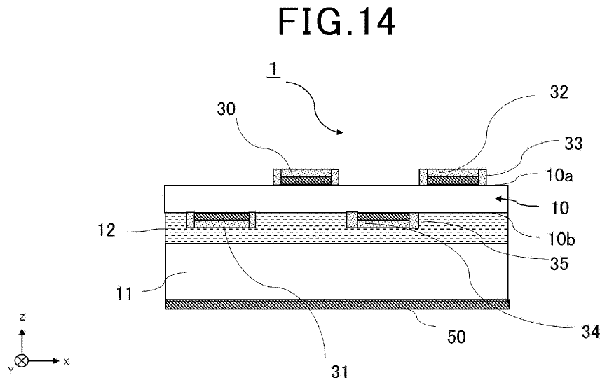

FIG. 14 is a schematic view of an example showing a portion of a cross-section taken along line I-I in FIG. 1 in a case where blackening layers are provided. As shown in FIG. 14, a blackening layer 32 may be provided on the front surface and a blackening layer 33 on the side surface of the thin film conductive layer 30, and a blackening layer 34 may be provided on the back surface and a blackening layer 35 on the side surface of the thin film conductive layer 31.

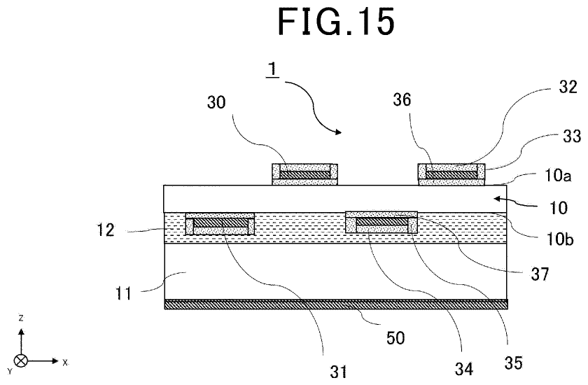

Furthermore, FIG. 15 is a schematic view of another example showing a portion of a cross-section taken along line I-I in FIG. 1 in a case where blackening layers are provided. As shown in FIG. 15, it is possible to form the blackening layers before forming the thin film conductive layers 30 and 31 on the dielectric substrate 10, and then form the thin film conductive layers and pattern the blackening layers and the thin film conductive layers to have the same dimensions by etching or the like, provide the blackening layers 36 and 37 between the thin film conductive layers 30 and 31 and the dielectric substrate 10, and provide the blackening layer 32 on the front surface and the blackening layer 33 on the side surface of the thin film conductive layer 30, and provide the blackening layer 34 on the back surface and the blackening layer 35 on the side surface of the thin film conductive layer 31.

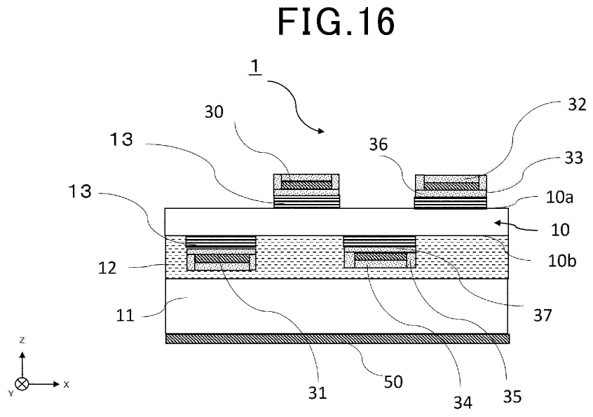

In addition, FIG. 16 is a schematic view of another example showing a portion of a cross-section taken along line I-I in FIG. 1 in a case where blackening layers are provided. As shown in FIG. 16, it is possible to form the blackening layers via the pressure-sensitive adhesive layers 13 before forming the thin film conductive layers 30 and 31 on the dielectric substrate 10, and then form the thin film conductive layers and pattern the pressure-sensitive adhesive layers, the blackening layers and the thin film conductive layers to have the same dimensions by etching or the like, provide the pressure-sensitive adhesive layers 13 and the blackening layers 36 and 37 between the thin film conductive layers 30 and 31 and the dielectric substrate 10, and provide the blackening layer 32 on the front surface and the blackening layer 33 on the side surface of the thin film conductive layer 30, and provide the blackening layer 34 on the back surface and the blackening layer 35 on the side surface of the thin film conductive layer 31.

The blackening layers may be formed by performing either sulfur blackening treatment or substitution blackening treatment. As a result of forming such blackening layers on the surfaces of the conductive elements, it is possible to obtain effects such as suppressing an increase in the resistance value of the conductive elements, and improving visibility by suppressing metallic gloss. Also, the conductive elements can be formed by providing blackening layers on the surfaces of the dielectric substrate 10 or by providing blackening layers via the pressure-sensitive adhesive layers 13, and then etching a multi-layered conductive layer in which thin film layers have been laminated. By forming such blackening layers between the dielectric substrate and the conductive elements, it is possible to improve the adhesion of the conductive elements to the dielectric substrate. The thickness of the blackening layers is preferably 200 nm or less. When the thickness is 200 nm or more, there is a possibility that the productivity may decrease. Furthermore, the surface roughness Ra of the blackening layers is 0.5 μm or more.

The thin film conductive layer 31 may include the support layer 11 on the surface on the opposite side to the dielectric substrate 10 (back surface). The thickness of the support layer 11 can be 5 μm or more and 250 μm or less. In addition, the thickness can be 10 μm or more and 200 μm or less. The support layer 11 is single-layered or multi-layered. As the material of the support layer 11, the same materials as the dielectric substrate 10 can be used. For example, the resin can be a single resin, a mixture, or a composite of a urethane resin, an acrylic resin, a polyamide, a polyimide, a polyamideimide, an epoxy resin, or a silicone resin. The support layer 11 can be an extruded film. The extruded film can be an unstretched film or a stretched film. Furthermore, the support layer 11 may be formed by being coated on the back surface of the electromagnetic wave attenuation substrate 20.

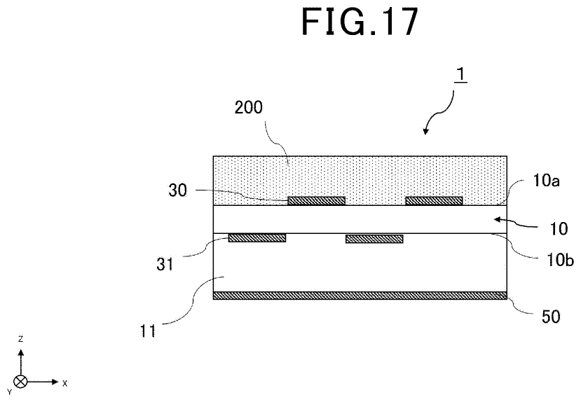

The thin film conductive layer 30 may include a top coat layer 200 on the surface on the opposite side to the dielectric substrate 10 (front surface). FIG. 17 is a schematic view showing a portion of a cross-section taken along line I-I in FIG. 1 in a case where the top coat layer 200 is provided. The flat plate inductor 50 may also include the top coat layer 200 on the surface on the opposite side to the dielectric substrate 10 (back surface). The thickness of the top coat layer 200 can be 0.1 μm or more and 50 μm or less. In addition, the thickness can be 1 μm or more and 5 μm or less. The top coat layer 200 is single-layered or multi-layered. The material of the top coat layer 200 can be a single resin, a mixture, or a composite of a urethane resin, an acrylic resin, a polyamide, a polyimide, a polyamideimide, an epoxy resin, or a silicone resin. Furthermore insulating particles, magnetic particles, conductive particles, or a mixture thereof may also be included. The particles can be inorganic particles. As a result of providing the top coat layer 200, the impedance is matched with the air through which radio waves propagate, and radio waves can be effectively attenuated by the thin film conductive layer. In addition, the thin film conductive layers 30 and 31 and the flat plate inductor 50 can be imparted with corrosion resistance, chemical resistance, heat resistance, abrasion resistance, impact resistance, and the like. For example, by using a crosslinked acrylic resin, a crosslinked epoxy resin, a polyamide, a polyimide, a polyamideimide, a silicone resin, or the like, it is possible to improve the solvent resistance and also the heat resistance. Furthermore, it is possible to improve the impact resistance by using a urethane resin or the like, and to improve the abrasion resistance by using a silicone resin.

Furthermore, in order to impart design properties, the top coat layer 200 may contain a pigment or the like. The pigments used include organic pigments and inorganic pigments. As the organic pigment, for example, an azo pigment, a lake pigment, an anthraquinone pigment, a phthalocyanine pigment, an isoindolinone pigment, a dioxazine pigment, or the like can be used. Examples of inorganic pigments that can be used include yellow lead, yellow iron oxide, cadmium yellow, titanium yellow, barium yellow, aureolin, molybdate orange, cadmium red, red iron oxide, red lead, cinnabar, mars violet, manganese violet, cobalt violet, cobalt blue, cerulean blue, ultramarine, Prussian blue, emerald green, chrome vermilion, chromium oxide, viridian, iron black, and carbon black. In addition, examples of inorganic white pigments that can be used include titanium oxide (titanium white), zinc oxide (zinc white), basic lead carbonate (lead white), basic lead sulfate, zinc sulfide, lithopone, and titanox. In particular, inorganic pigments have very high concealment, but in addition to the concealment, also have excellent light resistance (fade resistance) and chemical resistance, making them highly preferable in terms of durability and robustness when it is desirable to impart design to the top coat layer.

When the top coat layer 200 is multi-layered, it may be divided into a durability-imparting layer and a design-imparting layer. If necessary, a protective layer for protecting the design-imparting layer may be provided on the design-imparting layer. In addition, an adhesive layer or a pressure-sensitive adhesive layer may be provided on the surface in contact with the thin film conductive layer 30, and a durability-imparting layer and a design-imparting layer prepared separately may be attached to form the top coat layer 200.

When the top coat layer 200 is attached to the electromagnetic wave attenuation film of the present invention, the desired electromagnetic wave attenuation characteristics can be maintained by performing the attachment in a manner that prevents air bubbles or the like from entering between the top coat layer 200 and the thin film conductive layer 30.

When the electromagnetic wave attenuation film of the present invention is applied to a building material such as wallpaper, a pattern may be provided on the top coat layer 200 or the design-imparting layer in order to impart design properties. The type of pattern is not particularly limited, and any pattern can be used depending on the intended use of the building material such as wallpaper. For example, wood grain patterns, cork patterns, stone patterns, marble patterns, abstract patterns, and the like, which are widely used in the field of conventional building materials, can be used. Also, for example, when the purpose is simply to provide color or color adjustment, a single solid color may be used. Furthermore, if necessary, a pattern having unevenness may be provided. The type of pattern having unevenness is not particularly limited, and any pattern can be used depending on the intended use of the building material such as wallpaper. For example, wood grain patterns, stone grain patterns, Japanese paper patterns, marble patterns, cloth grain patterns, and geometric patterns, and the like, which are widely used in the field of conventional building materials such as wallpapers, can be used. In addition, a simple matte finish, a grained finish, a hairline finish, a suede finish, and the like, may be used. The method of forming the pattern having unevenness is not particularly limited, and any method of forming a pattern having unevenness can be used. For example, a mechanical embossing method using a metal embossing plate can be used.

In this way, by imparting design properties, when the electromagnetic wave attenuation film of the present invention is used as a building material, it becomes possible to harmonize the color tone and texture with the atmosphere of the space.

Investigations by the inventors have revealed that the attenuation due to the first mechanism varies depending on the admittance (the reciprocal of the electrical resistance) of the metal that constitutes the conductive elements. At an admittance (siemens/m) of 10⁷ or more, good attenuation of electromagnetic waves was obtained. Silver is known to be the material with the highest admittance among normal conductors, and the admittance is 61 to 66×10⁶, which results in an upper limit of the admittance of approximately 70,000,000. A metal with an admittance of 5×10⁶ or more and 7×10⁷ or less can be used. The metal constituting the conductive elements can be a ferromagnetic material, a paramagnetic material, a diamagnetic material, or an antiferromagnetic material. Examples of ferromagnetic metals include nickel, cobalt, iron, and alloys thereof. Examples of paramagnetic metals include aluminum, tin (β-tin), and alloys thereof. Examples of diamagnetic metals include gold, silver, copper, tin (α-tin), zinc, and alloys thereof. Examples of diamagnetic alloys include brass, which is an alloy of copper and zinc. Examples of antiferromagnetic metals include chromium. These metallic conductive elements have demonstrated good attenuation of electromagnetic waves.

### <Manufacturing Method>

An example of a manufacturing method of the electromagnetic wave attenuation film 1 will be described.

Although a variety of means of obtaining the electromagnetic wave attenuation film of the present invention can be considered, the manufacturing method described below is simple, and the arrangement accuracy of the thin film conductive layers is high.

First, the manufacturing method of the electromagnetic wave attenuation substrate 20 will be described. For this purpose, thin film conductive layers 30 and 31 each having a predetermined repeating pattern of conductive elements were simultaneously formed on both the front surface 10a and the back surface 10b of the dielectric substrate 10. Although the conductive elements may be formed by any method that can obtain a desired pattern, for example, a photolithography method can be used. Note that, if necessary, the front surface 10a and the back surface 10b of the dielectric substrate 10 may be subjected in advance to either sulfur blackening treatment or displacement blackening treatment to form blackening layers.

Examples of the material of the dielectric substrate 10 include, but are not limited to, polyesters such as polyethylene terephthalate (PET), polyarylene sulfides such as polyphenylene sulfide, polyolefins such as polyethylene and polypropylene, polyamides, polyimides, polyamideimides, polyethersulfones, polyetheretherketones, polycarbonates, acrylic resins, and polystyrene.

When using a photolithography method, a metal film is firstly formed on both the front surface 10a and the back surface 10b of the dielectric substrate 10 so as to enclose the entire region of the pattern to be finally obtained. The metal film may be formed by physical deposition such as vapor deposition or sputtering, or by attaching a metal foil or the like. Alternatively, the metal film may be formed by plating. The plating can be formed by electrolytic plating or electroless plating. The plating can be a copper plating, an electroless nickel plating, an electrolytic nickel plating, a zinc plating, an electrolytic chromium plating, or a laminate thereof. The metal film may be simultaneously formed on the front surface 10a and the back surface 10b or formed separately. When the metal films are formed separately, either one of the metal films can be formed first.

Next, a resist layer is formed on the metal film formed on the front surface 10a and the back surface 10b of the dielectric substrate 10. The resist layer may be formed by coating a normal resist solution and then drying the solution, but a method using a dry film resist is preferable because there is no risk of liquid dripping due to insufficient drying. The resist layer may be simultaneously formed on the front surface 10a side and the back surface 10b side or formed separately. When the resist layers are formed separately, either one of the resist layers can be formed first as in the case of the formation of the metal film.

Then, the front surface 10a and back surface 10b of the dielectric substrate 10 are simultaneously exposed to light via a material that blocks light in a patterned shape, such as a photomask. In the embodiment of the present invention, when a photolithography method is used, “simultaneous formation” refers to simultaneously carrying out an exposure step. The two photomasks on the front surface 10a side and the back surface 10b side typically have a different pattern shape and/or position. If the positions of the two photomasks can be appropriately controlled during exposure, the positional relationship between the thin film conductive layers 30 and 31 that are finally obtained will be as designed, and concerns regarding misalignment after formation or during use of the electromagnetic wave attenuation film can be minimized.

Thereafter, the resist layer is developed using a developer to remove unnecessary portions of the resist layer. The development may be performed simultaneously on the front surface 10a and the back surface 10b of the dielectric substrate 10, or performed separately, but simultaneous development is preferable because there is no concern of problems occurring that are caused by the developer flowing around to the opposite surface.

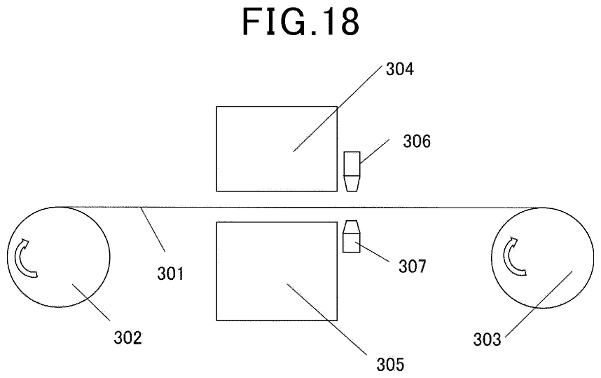

FIG. 18 is a schematic diagram showing a simultaneous exposure step. A sheet-shaped substrate 301 moves from an unwinding portion 302 to a winding portion 303, and while the front surface and the back surface of the substrate 301 are being observed using reading cameras 306 and 307, the front surface and the back surface are simultaneously exposed using the photomasks 304 and 305.

In addition, the metal layer is removed from those portions in which the resist layer has been removed and are exposed. The metal layer is generally removed by wet etching, but dry etching or any other method may be used as long as it is possible to selectively remove only the exposed portions. The metal layer may also be removed from the front surface 10a and the back surface 10b of the dielectric substrate 10 simultaneously, or removed separately, but it is convenient to perform the removal simultaneously if wet etching is used.

Finally, the resist layer remaining on the metal layer, from which unnecessary portions have been removed and a pattern has been formed, that is, on the thin film conductive layers 30 and 31, is removed. The resist layer may be removed from the front surface 10a and back surface 10b of the dielectric substrate 10 simultaneously, or removed separately, but it is convenient to perform the removal simultaneously. If there is a design reason that makes it advantageous to leave the resist layer on the thin film conductive layers 30 and 31, this step can be omitted.

Note that, as already described, the formation of the thin film conductive layers 30 and 31 on the dielectric substrate 10 does not have to be performed by a photolithography method. A printing method, an inkjet method, or any other forming method can be applied. In the present invention, “simultaneous formation” refers to simultaneous transfer when a printing method is used, and simultaneous deposition when an inkjet method is used.

Furthermore, in the embodiment of the present invention, the “metal film” does not have to be made of a metal. For example, it may be a conductive organic material such as PEDOT/PSS, or a conductive oxide such as InGaZnO.

After these steps are completed, if necessary, the thin film conductive layers 30 and 31 may be subjected to either sulfur blackening treatment or displacement blackening treatment to form blackening layers.

Next, the support layer 11 on which the flat plate inductor 50 has been formed is prepared. Note that the reason for performing this step after the formation of the thin film conductive layers 30 and 31 on the dielectric substrate 10 is simply for convenience of description, and it goes without saying that the order may be reversed, or both steps may be performed in parallel.

The support layer 11 on which the flat plate inductor 50 has been formed can typically be obtained by laminating the flat plate inductor 50 onto the support layer 11. As the material of the support layer 11, the same materials as the dielectric substrate 10 can be used. Then, in the same manner as forming the metal film on the dielectric substrate 10, the flat plate inductor 50 made of a metal film can be formed on the support layer 11. Alternatively, the flat plate inductor 50 may be obtained by attaching a cast or rolled metal plate to the support layer 11.

As the material of the support layer 11, the same materials as the dielectric substrate 10 can be used. The support layer 11 may be completely made of the same material as the dielectric substrate 10, or a different material may be used.

In addition, the material of the flat plate inductor 50 may be the same as that of the thin film conductive layers 30 and 31. The flat plate inductor 50 may be completely made of the same material as the dielectric thin film conductive layers 30 and 31, or a different material may be used.

Then, the electromagnetic wave attenuation film 1 can be obtained by attaching, to the back surface 10b side of the dielectric substrate 10 (electromagnetic wave attenuation substrate 20), on which the thin film conductive layers 30 and 31 have been formed, the support layer 11, on which the flat plate inductor 50 has been formed, via the opposite side to the flat plate inductor 50.

Furthermore, as another method for obtaining the electromagnetic wave attenuation film of the present invention, the thin film conductive layers 30 and 31 may be formed simultaneously on both the front surface 10a and the back surface 10b of the dielectric substrate 10, and then the support layer 11 may be laminated on the back surface 10b side of the dielectric substrate 10, and the flat plate inductor 50 may be formed on the opposite side of the support layer 11 to the dielectric substrate 10.

When providing the top coat layer 200, the electromagnetic wave attenuation film may be attached via an pressure-sensitive adhesive layer, but the method of forming the top coat layer 200 is not limited to this, and a coating method or the like may also be used. The coating method may be appropriately selected from methods used in film production. Examples of the coating method include gravure coating, reverse coating, gravure reverse coating, die coating, and flow coating.

### EXAMPLES

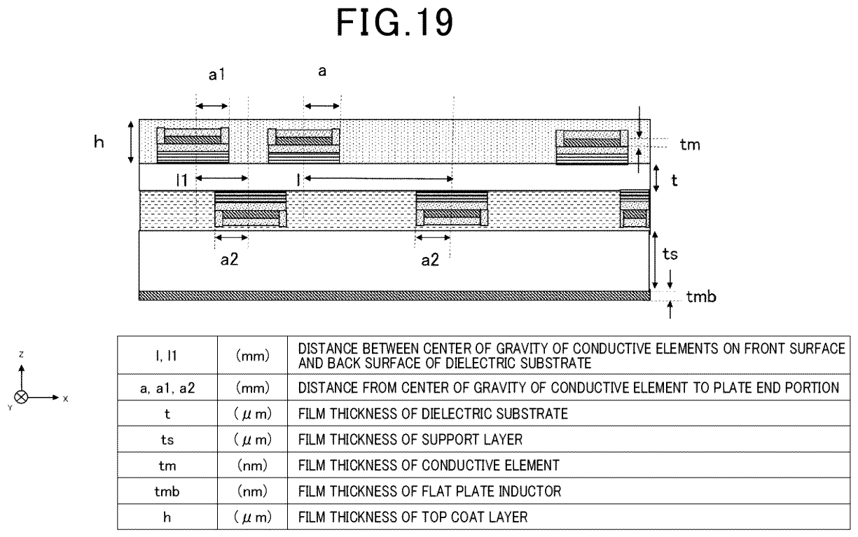

The embodiments of the present invention will be further described using examples. FIG. 19 is a schematic diagram showing a portion of a cross-section of the electromagnetic wave attenuation film described in Examples 1 to 6. 1 and 11 represent the distance between the center of gravity of the conductive elements on the front surface and the back surface of the dielectric substrate; a, a1 and a2 represent the distance from the center of gravity of the conductive elements to the plate end portion; t represents the film thickness of the dielectric substrate; ts represents the film thickness of the support layer; tm represents the film thickness of the thin film conductive layers; tmb represents the film thickness of the flat plate inductor; and h represents the film thickness of the top coat layer. Note that, in Examples 1 to 7, because the conductive elements have the same shape and the same dimensions, a, a1 and a2 are equal.

When conductive elements of the same shape are uniformly arranged as in the first embodiment shown in FIG. 1, 1 is equal to 11. On the other hand, when there is a mixture of conductive elements in which the distances between them are different as in the second embodiment shown in FIGS. 12, 1 and 11 take different values. The structures of the electromagnetic wave attenuation films of Examples 1 to 6 are shown in Table 1. Examples 1 to 5 correspond to examples of the first embodiment, and Example 6 corresponds to an example of the second embodiment.

TABLE 1

| | | Example 1 | | Example 2 | | Example 3 | | Example 4 | | Example 5 | | Example 6 |
|---|---|---|---|---|---|---|---|---|---|---|---|---|
| | | | | | | | | | | | | Second |
| | | First embodiment | | | | | | | | | | embodiment |
| Structure | l (mm) | 1.4 | | 2.6 | | 2.1 | | 1.0 | | 1.2 | | 1.0 |
| | a (mm) | 0.5 | | 0.5 | | 0.5 | | 0.5 | | 0.5 | | 0.5 |
| | l/a | 2.8 | | 5.2 | | 4.2 | | 2.0 | | 2.2 | | 2.0 |
| | l1 (mm) | — | | — | | — | | — | | — | | 0.7 |
| | a1 (mm) | — | | — | | — | | — | | — | | 0.5 |
| | t (μm) | 50 | | 50 | | 50 | | 50 | | 50 | | 50 |
| | ts (μm) | 100 | | 100 | | 200 | | 100 | | 100 | | 100 |
| | tm (nm) | 500 | | 500 | | 500 | | 500 | | 500 | | 500 |
| | tmb (nm) | 50 | | 50 | | 50 | | 50 | | 50 | | 50 |
| | h (μm) | — | | — | | — | | — | | 75 | | — |
| Evaluation | Positional shift | None | | None | | None | | None | | None | | None |
| results | after bending | | | | | | | | | | | |
| | test | | | | | | | | | | | |
| | Absorption | 74 | GHz | 74 | GHz | 79 | GHz | 78 | GHz | 75 | GHz | 58 GHz, |
| | frequency | | | | | | | | | | | 67 GHz |
| | Absorption | −13 | dB | −14 | dB | −17 | dB | −15 | dB | −10 | dB | −13 dB, |

| | | | | | | |
|---|---|---|---|---|---|---|
| amount | | | | | | −14 dB |
| Weather | Fair | Fair | Fair | Fair | Good | Fair |
| resistance test | | | | | | |

| | | | | | | |
|---|---|---|---|---|---|---|
| Overall evaluation | Good | Good | Good | Good | Excellent | Good |

### <Manufacturing Method>

A common manufacturing method used to produce the electromagnetic wave attenuation films according to Examples 1 to 4 will be described. A copper layer having a thickness of 500 nm was formed by sputtering on both sides of a PET sheet having a thickness of 50 μm. Next, after the copper layer was washed, a dry resist film was laminated onto the copper layer on both sides of the PET sheet. Both sides were then exposed simultaneously through photomasks having a plate-shaped pattern, and then portions of the underlying thin film conductive layers were exposed by simultaneously developing an acrylic negative resist layer on both sides using a mixed alkaline aqueous solution of sodium carbonate and sodium bicarbonate, and removing the unnecessary resist.

Next, the copper layer on both sides that were partially covered by the resist layer were simultaneously immersed in a ferric chloride solution, and the exposed parts of the copper layer were removed by etching. Then, the remaining resist layer was simultaneously removed from both sides with an alkaline solution to obtain a plate-shaped copper pattern. Next, the surface and sides of the copper pattern were subjected to blackening treatment.

Then, a PET film having a thickness of 100 μm was laminated to the back surface side of the film, which had the plate-shaped copper pattern on both sides, via a pressure-sensitive adhesive layer to form the support layer, and further, an aluminum foil having a thickness of 50 nm was laminated to the back side of the support layer via a pressure-sensitive adhesive layer to form the flat plate inductor. The above represents the manufacturing procedure of Examples 1 to 4 according to the first embodiment.

The manufacturing method used to produce the electromagnetic wave attenuation film according to Example 5 will be described. Using the same manufacturing procedure as in Examples 1 to 4, after forming the thin film conductive layers on the front surface and the back surface of the dielectric substrate, forming the support layer via the pressure-sensitive adhesive layer on the thin film conductive layer on the back surface side, and then forming the flat plate inductor on the back surface of the support layer, the top coat layer was formed on the front surface side of the dielectric substrate. The top coat layer was formed by the procedure described below.

To an acrylic resin composition serving as the main component composed of a mixture of 80 parts by mass of methyl methacrylate monomer and 20 parts by mass of cyclohexyl methacrylate were added, with respect to 100 parts by mass of the solid content of the acrylic resin composition, 6 parts by mass of hydroxyphenyltriazine-based ultraviolet absorber (“ADEKA STAB LA-46”, manufactured by ADEKA Corporation), 6 parts by mass of a hydroxyphenyltriazine-based ultraviolet absorber of a different composition (“Tinuvin 479”, manufactured by Chiba Specialty Chemicals Co., Ltd.), 3 parts by mass of a benzotriazole-based ultraviolet absorber (“Tinuvin 329”, manufactured by Chiba Specialty Chemicals Co., Ltd.), and

5 parts by mass of a hindered amine-based radical scavenger (“Tinuvin 292”, manufactured by Chiba Specialty Chemicals Co., Ltd.), and after mixing together the primary solution obtained by further addition of an ethyl acetate solvent for solid content adjustment to a solid content amount of 33 parts by mass, and a hexamethylene diisocyanate-based curing agent solution obtained by adding an ethyl acetate solvent for solid content adjustment to a solid content amount of 75 parts by mass such that the ratio between the primary solution and the curing agent solution was 10:1 (the ratio between the number of hydroxyl groups in the primary solution and the number of isocyanate groups in the curing agent solution at this time being 1:2), a coating solution was obtained by further adding ethyl acetate as a solvent component to adjust the solid content amount to 20 parts by mass, and then the coating solution was coated such that the thickness after evaporation of the solvent became 6 μm to obtain the top coat layer. The above represents the manufacturing procedure of Example 5 according to the first embodiment.

The manufacturing method used to produce the electromagnetic wave attenuation film according to Example 6 will be described. Using the same manufacturing procedure as in Examples 1 to 4, the thin film conductive layers were formed such that, in a single plane, the positions of the thin film conductive layers were a mixture of 50% of the total being combinations in which the thin film conductive layers on the front surface and the back surface of the dielectric substrate were overlapping in the plane direction (I<2a), and 50% of the total being combinations that were not overlapping (I≥2a). Next, the support layer was formed on the thin film conductive layer on the back surface side via a pressure-sensitive adhesive layer, and then the flat plate inductor was formed on the back surface of the support. The above represents the manufacturing procedure of Example 6 according to the second embodiment.

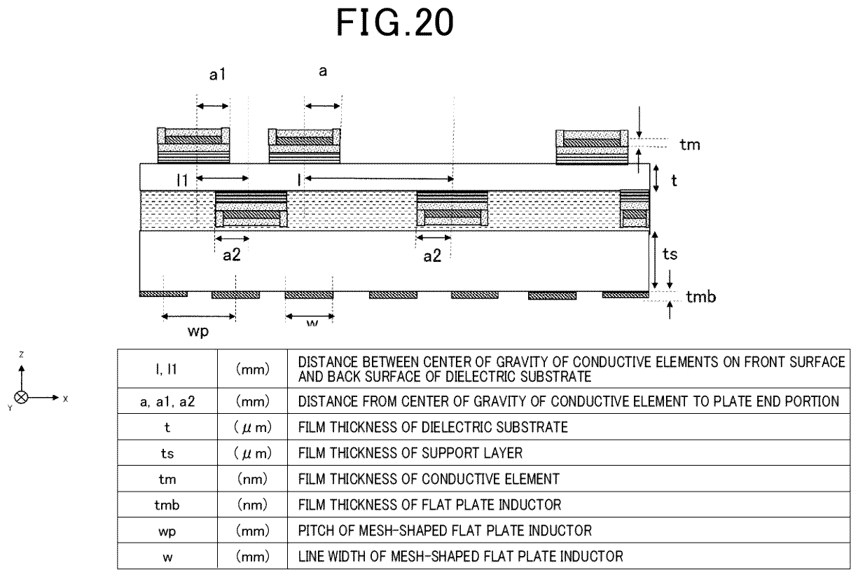

Example 7 differs from Examples 1 to 5 in that the flat plate inductor has a mesh shape. FIG. 20 is a schematic diagram showing a portion of a cross-section of the electromagnetic wave attenuation film described in Example 7. wp represents the pitch of the mesh-shaped flat plate inductor, and w represents the line width of the mesh-shaped flat plate inductor. The structure of the electromagnetic wave attenuation film of Example 7 is shown in Table 2.

The manufacturing method used to produce the electromagnetic wave attenuation film according to Example 7 will be described. Using the same manufacturing procedure as in Examples 1 to 4, the thin film conductive layers were formed on the front surface and the back surface of the dielectric substrate, and the support layer was formed on the thin-film conductive on the back surface side layer via a pressure-sensitive adhesive layer. Then, a mesh-shaped flat plate inductor having a copper pattern with a film thickness of 500 nm formed by etching one side was arranged and formed by lamination on the back surface of the support layer via a pressure-sensitive adhesive layer, with the copper pattern side being on the support layer side. In this case, the pitch of the mesh-shaped copper pattern was 0.44 mm, and the line width of the copper pattern was 0.085 mm.

TABLE 2

| | | Example 7 |
|---|---|---|
| | | First |
| | | embodiment |
| Structure | l (mm) | 1.4 |
| | a (mm) | 0.5 |
| | l/a | 2.8 |
| | l1 (mm) | — |
| | a1 (mm) | — |
| | t (μm) | 50 |
| | ts (μm) | 100 |
| | tm (nm) | 500 |
| | tmb (nm) | 500 |
| | wp (mm) | 0.44 |
| | w (mm) | 0.085 |
| | h (μm) | — |
| Evaluation | Positional | None |
| results | shift after | |
| | bending test | |

| | | |
|---|---|---|
| Absorption | 75 | GHz |
| frequency | | |
| Absorption | −11 | dB |

| | |
|---|---|
| amount | |
| Weather | Fair |
| resistance test | |

| | |
|---|---|
| Overall evaluation | Good |

Examples 8 to 10 are electromagnetic wave attenuation films exhibiting absorption at two frequencies as a result of changing between the dimensions of the thin film conductive layers that are arranged on the front surface and the back surface of the dielectric body. The structures of the electromagnetic wave attenuation films of Examples 8 to 10 are shown in Table 3; a and a1 are equal.

The manufacturing method used to produce the electromagnetic wave attenuation films according to Examples 8 to 10 used the same manufacturing procedure as in Examples 1 to 4, in which the thin film conductive layers were formed on the front surface and the back surface of the dielectric substrate, and the support layer was formed on the thin-film conductive on the back surface side layer via a pressure-sensitive adhesive layer. The flat plate inductor was formed by laminating an aluminum foil having a thickness of 50 nm on the back surface of the support layer via a pressure-sensitive adhesive layer.

TABLE 3

| | | Example 8 | Example 9 | Example 10 |
|---|---|---|---|---|
| | | First embodiment | | |
| Structure | l (mm) | 2.0 | 1.5 | 2.3 |
| | a (mm) | 0.7 | 0.7 | 1.1 |
| | l/a | 3.1 | 2.3 | 2.1 |
| | l1 (mm) | 2.0 | 1.5 | 2.3 |
| | a2 (mm) | 1.4 | 0.9 | 1.2 |
| | t (μm) | 50 | 50 | 50 |
| | ts (μm) | 150 | 150 | 150 |
| | tm (nm) | 100 | 100 | 100 |
| | tmb (nm) | 50 | 50 | 50 |
| | h (μm) | — | — | — |
| Evaluation | Positional shift | None | None | None |
| results | after bending test | | | |
| | Absorption | 28 GHz, | 39 GHz, | 28 GHz, |
| | frequency | 60 GHz | 60 GHz | 39 GHz |
| | Absorption | −11 dB, | −11 dB, | −10 dB, |
| | amount | −21 dB | −14 dB | −13 dB |
| | Weather | Fair | Fair | Fair |
| | resistance test | | | |

| | | | |
|---|---|---|---|
| Overall evaluation | Good | Good | Good |

Examples 11 to 15 are electromagnetic wave attenuation films in which the dimensions of the support layer have been changed. In the same manner as in Examples 1 to 4, the first embodiment shown in FIG. 1 is adopted. The structures of the electromagnetic wave attenuation films of Examples 11 to 15 are shown in Table 4. a, a1 and a2 are equal.

The manufacturing method used to produce the electromagnetic wave attenuation films according to Examples 11 to 15 used the same manufacturing procedure as in Examples 1 to 4, in which the thin film conductive layers were formed on the front surface and the back surface of the dielectric substrate, and the support layer was formed on the thin-film conductive on the back surface side layer via a pressure-sensitive adhesive layer. The flat plate inductor was formed by laminating an aluminum foil having a thickness of 50 nm on the back surface of the support layer via a pressure-sensitive adhesive layer.

TABLE 4

| | | Example 11 | | Example 12 | | Example 13 | | Example 14 | | Example 15 | |
|---|---|---|---|---|---|---|---|---|---|---|---|
| | | First embodiment | | | | | | | | | |
| Structure | l (mm) | 2.8 | | 2.8 | | 2.8 | | 2.0 | | 0.9 | |
| | a (mm) | 1.4 | | 1.4 | | 1.4 | | 1.0 | | 0.4 | |
| | l/a | 2.1 | | 2.1 | | 2.1 | | 2.1 | | 2.3 | |
| | l1 (mm) | — | | — | | — | | — | | — | |
| | a1 (mm) | — | | — | | — | | — | | — | |
| | t (μm) | 50 | | 50 | | 50 | | 50 | | 50 | |
| | ts (μm) | 50 | | 100 | | 100 | | 100 | | 25 | |
| | tm (nm) | 500 | | 500 | | 500 | | 500 | | 500 | |
| | tmb (nm) | 50 | | 50 | | 50 | | 50 | | 50 | |
| | h (μm) | — | | — | | — | | — | | — | |
| Evaluation | Positional | None | | None | | None | | None | | None | |
| results | shift after | | | | | | | | | | |
| | bending test | | | | | | | | | | |
| | Absorption | 31 | GHz | 29 | GHz | 29 | GHz | 40 | GHz | 100 | GHz |
| | frequency | | | | | | | | | | |
| | Absorption | −15 | dB | −15 | dB | −15 | dB | −28 | dB | −26 | dB |

| | | | | | |
|---|---|---|---|---|---|
| amount | | | | | |
| Weather | Fair | Fair | Fair | Fair | Fair |
| resistance test | | | | | |

| | | | | | |
|---|---|---|---|---|---|
| Overall evaluation | Good | Good | Good | Good | Good |

Examples 16 and 17 are electromagnetic wave attenuation films in which the dimensions of the support layer have been changed. In the same manner as in Examples 1 to 4, the first embodiment shown in FIG. 1 is adopted. The structures of the electromagnetic wave attenuation films of Examples 16 to 17 are shown in Table 5. a, a1 and a2 are equal.

In Examples 16 and 17, after forming the flat plate inductor on the back surface of the support layer using the same manufacturing method as in Examples 11 to 15, the top coat layer was formed on the front surface side of the dielectric substrate using the same manufacturing method as in Example 5.

TABLE 5

| | | Example 16 | Example 17 |
|---|---|---|---|
| | | First embodiment | |
| Structure | l (mm) | 2.8 | 2.8 |
| | a (mm) | 1.4 | 1.4 |
| | l/a | 2.1 | 2.1 |
| | l1 (mm) | — | — |
| | a1 (mm) | — | — |
| | t (μm) | 50 | 50 |
| | ts (μm) | 50 | 100 |
| | tm (nm) | 500 | 500 |
| | tmb (nm) | 50 | 50 |
| | h (μm) | 50 | 50 |
| Evaluation | Positional | None | None |
| results | shift after | | |
| | bending test | | |

| | | | | |
|---|---|---|---|---|
| Absorption | 30 | GHz | 28 | GHz |
| frequency | | | | |
| Absorption | −21 | dB | −21 | dB |

| | | |
|---|---|---|
| amount | | |
| Weather | Good | Good |
| resistance test | | |

| | | |
|---|---|---|
| Overall evaluation | Excellent | Excellent |

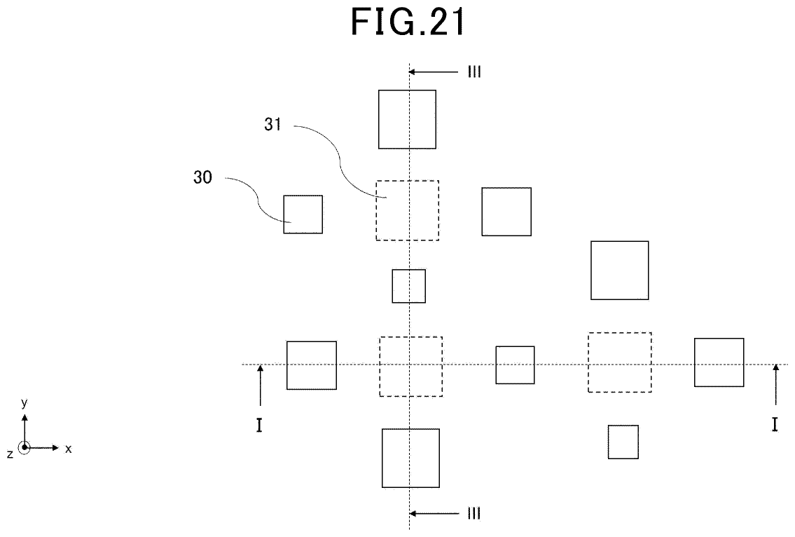

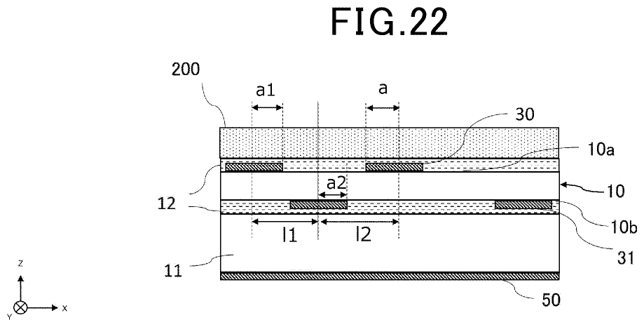

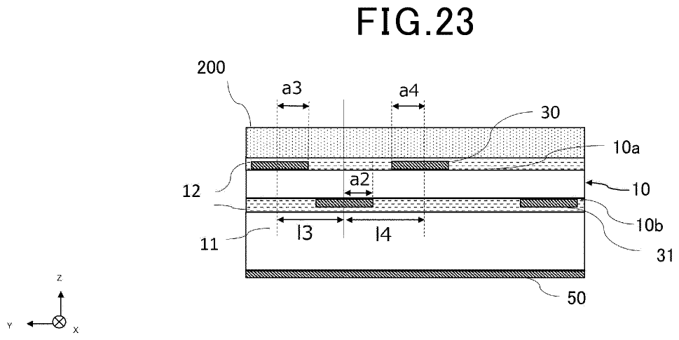

Example 18 is an electromagnetic wave attenuation film in which the dimensions of adjacent thin film conductive layers on the front surface of the dielectric body are different. FIG. 21 is a schematic plan view showing a portion of the electromagnetic wave attenuation film described in Example 18. FIG. 22 is a schematic diagram showing a portion of a cross-section taken along line I-I of the electromagnetic wave attenuation film described in Example 18. FIG. 23 is a schematic diagram showing a portion of a cross-section taken along line III-III of the electromagnetic wave attenuation film described in Example 18. 11 to 14 represent the distance between the center of gravity of adjacent conductive elements on the front surface and the back surface of the dielectric substrate, and a, and a1 to a4 represent the distance from the center of gravity of each conductive element to the plate end portion. The structure of the electromagnetic wave attenuation film of Example 18 is shown in Table 6.

In the manufacturing method that produced the electromagnetic wave attenuation film according to Example 18, after forming the flat plate inductor on the back surface of the support layer using the same manufacturing method as in Examples 11 to 15, the top coat layer was formed on the front surface side of the dielectric substrate using the same manufacturing method as in Example 5.

TABLE 6

| | | Example 18 |
|---|---|---|
| | | First embodiment |
| Structure | l1 (mm) | 1.3 |
| | a2 (mm) | 0.6 |
| | l1/a2 | 2.1 |
| | l2 (mm) | 1.2 |
| | a1 (mm) | 0.5 |
| | l3 (mm) | 1.2 |
| | a (mm) | 0.5 |
| | l4 (mm) | 1.2 |
| | a3 (mm) | 0.5 |
| | a4 (mm) | 0.5 |
| | t (μm) | 50 |
| | ts (μm) | 175 |
| | tm (nm) | 500 |
| | tmb (nm) | 50 |
| | h (μm) | 50 |
| Evaluation | Positional shift | None |
| results | after bending test | |

| | | |
|---|---|---|
| Absorption | 60 | GHz |
| frequency | | |
| Absorption | −26 | dB |

| | |
|---|---|
| amount | |
| Weather | Good |
| resistance test | |

| | |
|---|---|
| Overall evaluation | Excellent |

Example 19 and Reference Example 1 are electromagnetic wave absorption films according to an applied mode of the first embodiment described above. The size (a′) of the conductive elements on the front surface is set smaller than the size (a) of the conductive elements on the back surface in Example 19, and is set larger in Reference Example 1. The structures of the electromagnetic wave absorption films of Example 19 and Reference Example 1 are shown in Table 7. 1, a, and a′ represent the dimensions shown in FIGS. 10A and 10B. aₘₐₓ indicates the maximum size among the conductive elements. Note that the value of s (see FIG. 10B) is determined so as to optimize the amount of attenuation based on the size of the conductive elements, and is 1,034.157 μm in Example 19, and 246.573 μm in Reference Example 1.

The manufacturing method that produced the electromagnetic wave attenuation films according to Example 19 and Reference Example 1 was performed using the same manufacturing procedure as in Examples 1 to 4.

TABLE 7

| | | | Reference |
|---|---|---|---|
| | | Example 19 | Example 1 |
| | | First embodiment (application) | |
| Structure | l (mm) | 3.751 | 3.935 |
| | a (mm) | 1.501 | 1.053 |
| | a′ (mm) | 1.049 | 1.483 |
| | l/aₘₐₓ | 2.499 | 2.653 |
| | t (μm) | 50 | 50 |
| | ts (μm) | 175 | 175 |
| | tm (nm) | 500 | 500 |
| | tmb (nm) | 50 | 50 |
| | h (μm) | — | — |
| Evaluation | Positional shift | None | None |
| results | after bending test | | |
| | Absorption | 27.5 GHz | 28.3 GHz |
| | frequency | 39 GHz | 38.4 GHz |
| | Absorption amount | −17 dB | −21 dB |
| | (before bending) | −20 dB | −9 dB |
| | Weather resistance | Fair | Fair |
| | test | | |

| | | |
|---|---|---|
| Overall evaluation | Good | Fair |

Similarly, Reference Examples 2 and 3 are electromagnetic wave absorption films according to an applied mode of the first embodiment described above. The size of the conductive elements on the front surface is set smaller than the size of the conductive elements on the back surface in Reference Example 2 and is set larger in Reference Example 3. The structures of the electromagnetic wave absorption films of Reference Examples 2 and 3 are shown in Table 8. 1, a, and a′ represent the dimensions shown in FIGS. 10A and 10B. aₘₐₓ indicates the maximum size among the conductive elements. Note that the value of s (see FIG. 10B) is determined so as to optimize the amount of attenuation based on the size of the conductive element, and is 102.091 μm in Reference Example 2, and 350.492 μm in Reference Example 3.

The manufacturing method that produced the electromagnetic wave attenuation films according to Reference Examples 2 and 3 was performed using the same manufacturing procedure as in Examples 1 to 4.

TABLE 8

| | | Reference | Reference |
|---|---|---|---|
| | | Example 2 | Example 3 |
| | | First embodiment (application) | |
| Structure | l (mm) | 3.867 | 4.232 |
| | a (mm) | 1.423 | 1.223 |
| | a′ (mm) | 1.210 | 1.419 |
| | l/aₘₐₓ | 2.717 | 2.982 |
| | t (μm) | 50 | 50 |
| | ts (μm) | 175 | 175 |
| | tm (nm) | 500 | 500 |
| | tmb (nm) | 50 | 50 |
| | h (μm) | — | — |
| Evaluation | Positional shift | — | — |
| results | after bending test | | |
| | Absorption | 29.4 GHz | 29.25 GHz |
| | frequency | 34.25 GHz | 34.25 GHz |
| | Absorption amount | −22 dB | −37 dB |
| | | −20 dB | −10 dB |
| | Weather resistance | — | — |
| | test | | |

| | | |
|---|---|---|
| Overall evaluation | Good | Good |

### <Common Evaluation Items>

The electromagnetic wave attenuation films according to Examples 1 to 19 manufactured by the manufacturing method described above were subjected to a bending test, and the electromagnetic wave attenuation characteristics and the weather resistance were evaluated.

### (Bending Test)

A bending test of the electromagnetic wave attenuation film of Examples 1 to 19 was performed. Using the electromagnetic wave attenuation film produced in each example, a bending test was performed by sandwiching a sample between a set of two bending R jigs (mandrels), and after the test, the position of the conductive elements of the test piece was observed under a microscope to confirm whether there was any positional shift between the thin film conductive layers. The evaluation results are shown in Tables 1 to 7.

### (Electromagnetic Wave Attenuation Characteristics)

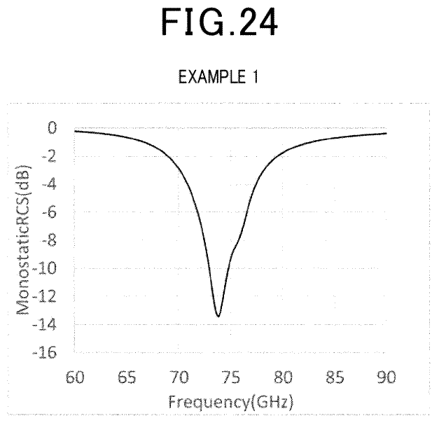

Using the configuration after the bending test, a simulation of the electromagnetic wave absorption characteristics was performed. The evaluation results are shown in Tables 1 to 6. FIGS. 24 to 42 show graphs of monostatic RCS attenuation at each frequency.

FIG. 24 is a graph showing the electromagnetic wave attenuation characteristics of Example 1. Good absorption characteristics of −13 dB were obtained at 74 GHz.

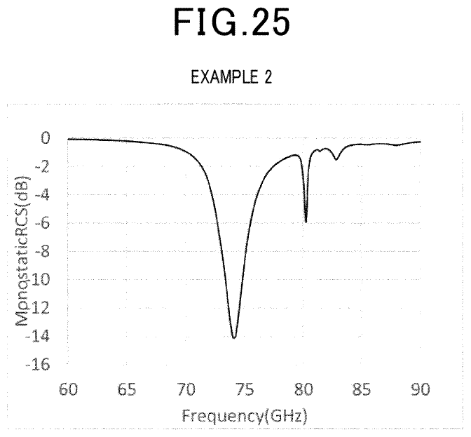

FIG. 25 is a graph showing the electromagnetic wave attenuation characteristics of Example 2. Good absorption characteristics of −14 dB were obtained at 74 GHz.

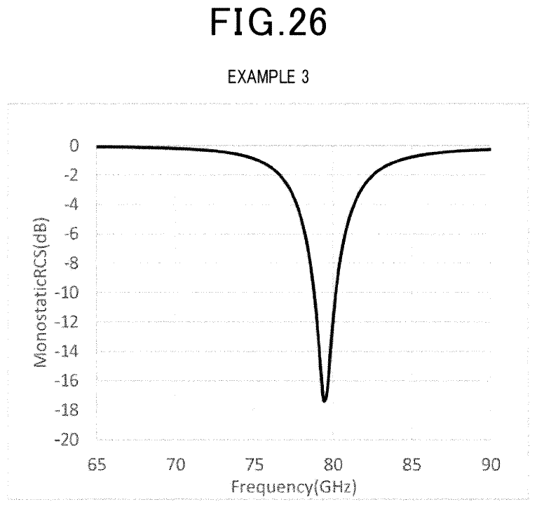

FIG. 26 is a graph showing the electromagnetic wave attenuation characteristics of Example 3. Good absorption characteristics of −17 dB were obtained at 79 GHz.

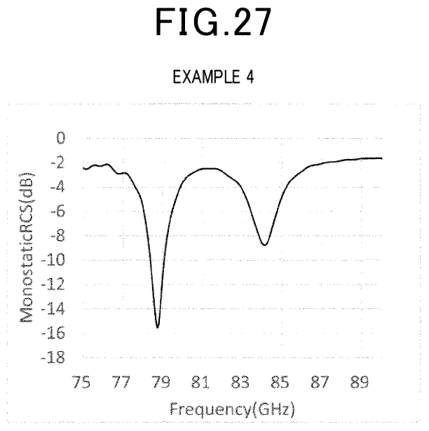

FIG. 27 is a graph showing the electromagnetic wave attenuation characteristics of Example 4. Good absorption characteristics of −15 dB were obtained at 78 GHz.

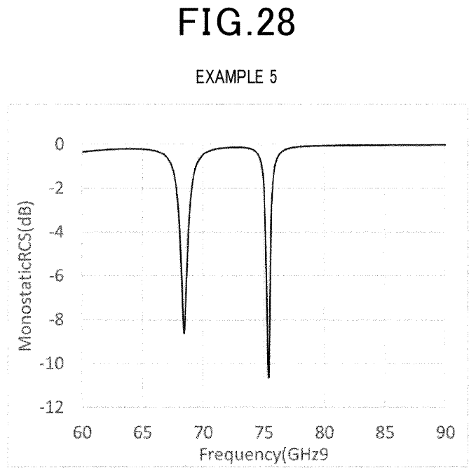

FIG. 28 is a graph showing the electromagnetic wave attenuation characteristics of Example 5. Good absorption characteristics of −10 dB were obtained at 75 GHz.

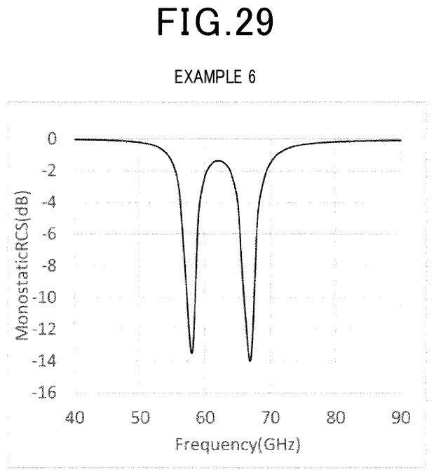

FIG. 29 is a graph showing the electromagnetic wave attenuation characteristics of Example 6. Good absorption characteristics of −13 dB and −14 dB were obtained at 58 GHz and 67 GHz, respectively.

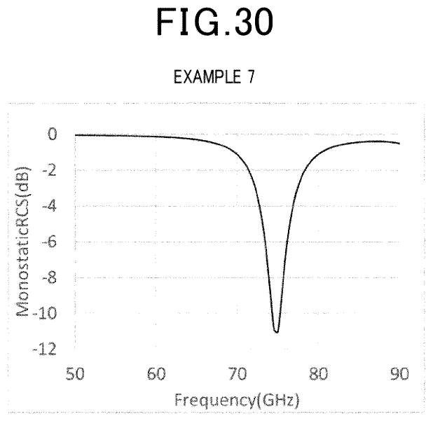

FIG. 30 is a graph showing the electromagnetic wave attenuation characteristics of Example 7. Good absorption characteristics of −11 dB were obtained at 75 GHz.

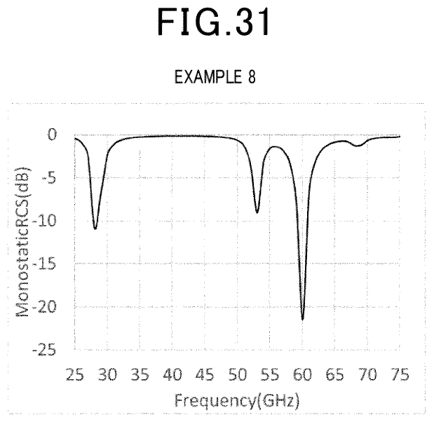

FIG. 31 is a graph showing the electromagnetic wave attenuation characteristics of Example 8. Good absorption characteristics of −11 dB were obtained at 28 GHz, and −21 dB at 60 GHz.

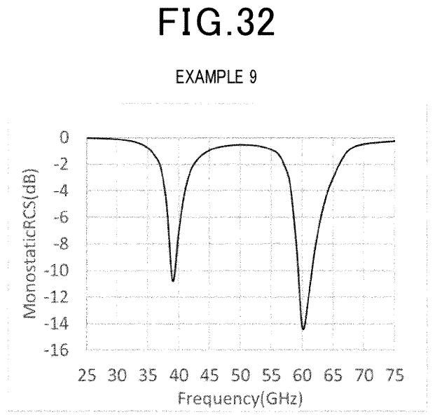

FIG. 32 is a graph showing the electromagnetic wave attenuation characteristics of Example 9. Good absorption characteristics of −11 dB were obtained at 39 GHz, and −14 dB at 60 GHz.

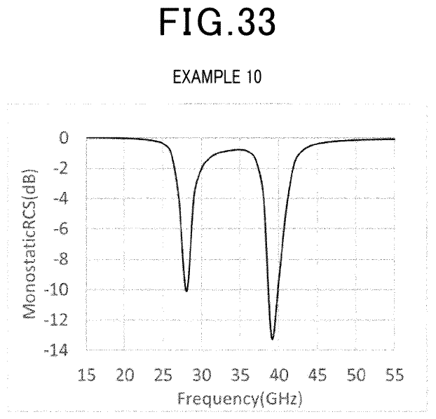

FIG. 33 is a graph showing the electromagnetic wave attenuation characteristics of Example 10. Good absorption characteristics of −10 dB were obtained at 28 GHz, and −13 dB at 39 GHz.

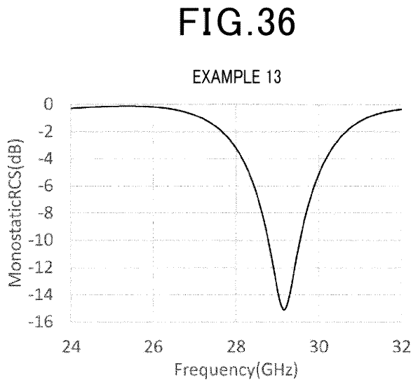

FIG. 36 is a graph showing the electromagnetic wave attenuation characteristics of Example 13. Good absorption characteristics of −15 dB were obtained at 29 GHz.

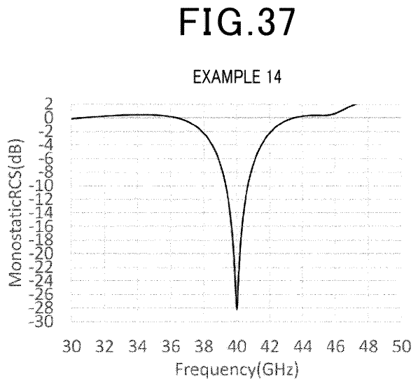

FIG. 37 is a graph showing the electromagnetic wave attenuation characteristics of Example 14. Good absorption characteristics of −28 dB were obtained at 40 GHz.

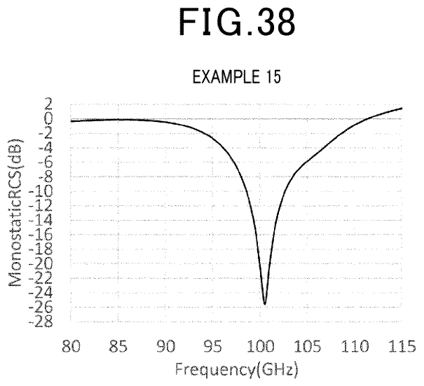

FIG. 38 is a graph showing the electromagnetic wave attenuation characteristics of Example 15. Good absorption characteristics of −26 dB were obtained at 100 GHz.

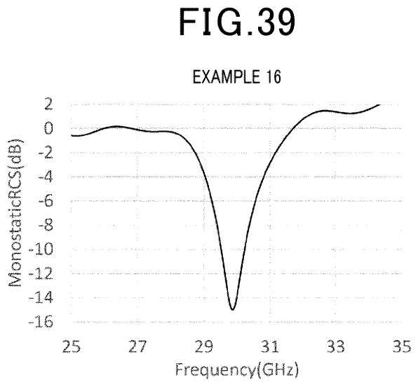

FIG. 39 is a graph showing the electromagnetic wave attenuation characteristics of Example 16. Good absorption characteristics of −15 dB were obtained at 30 GHz.

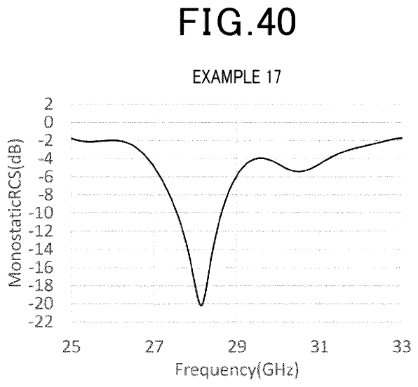

FIG. 40 is a graph showing the electromagnetic wave attenuation characteristics of Example 17. Good absorption characteristics of −21 dB were obtained at 28 GHz.

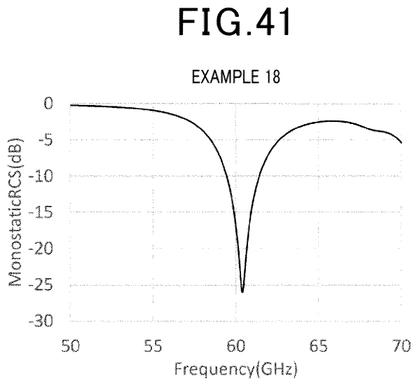

FIG. 41 is a graph showing the electromagnetic wave attenuation characteristics of Example 18. Good absorption characteristics of −26 dB were obtained at 60 GHz.

### (Weather Resistance)

In addition, the produced electromagnetic wave attenuation film was pressure bonded to a stainless steel plate via a pressure-sensitive adhesive layer, and after performing exposure corresponding to 10 years of outdoor exposure using a Sunshine Weather Meter, the surface of the electromagnetic wave attenuation film was wiped with a cotton cloth to confirm the preservation state of the top coat layer, or the electromagnetic wave attenuation layer including the electromagnetic wave attenuation substrate, the support layer, and the flat plate inductor. The evaluation results are shown in Tables 1 to 6. Those cases where none of the layers were affected after wiping were rated as Good, and those cases where peeling occurred to an extent that did not interfere with practical use were rated as Fair.

### (Actual Measurements)

In order to examine the validity of the attenuation mechanism based on the experimental results, the amount of electromagnetic wave attenuation was actually measured for the electromagnetic wave attenuation film according to Example 4. The procedure for the actual measurements was as follows.

Two metal plates of the same dimensions were prepared, and the electromagnetic wave attenuation film of Example 4 was attached to one of the plates so as to cover the entire plate. In a radio wave anechoic chamber, radio waves were irradiated onto metal plates with an attached electromagnetic wave attenuation film and a metal plate without the film, and the amount of reflected radio waves was measured using a network analyzer (Model E5071C, manufactured by Keysight Technologies Inc.). The monostatic RCS attenuation was evaluated by taking the reflection amount of the metal plate without an attached electromagnetic wave attenuation film as 100 (reference). As a result, as in FIG. 27, good absorption characteristics of −15 dB were obtained at 78 GHz.

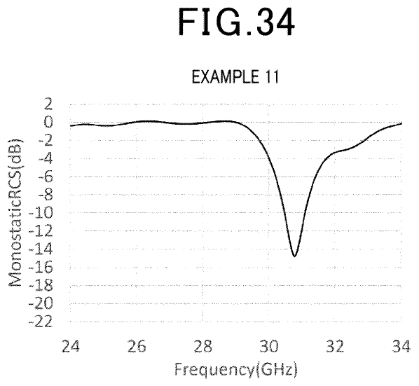

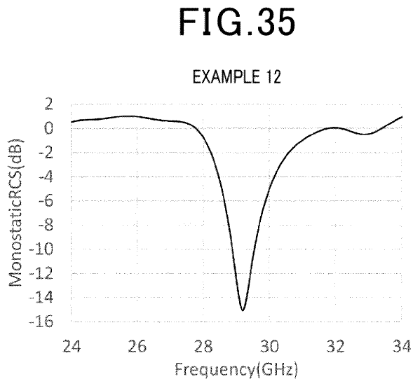

The electromagnetic wave attenuation films according to Examples 11 and 12, as in Example 4, were also subjected to an actual measurement of the amount of electromagnetic wave attenuation. The evaluation results are shown in Table 4. FIGS. 34 and 35 show graphs of actual measurements of monostatic RCS attenuation at each frequency.

FIG. 34 is a graph showing the electromagnetic wave attenuation characteristics of Example 11. Good absorption characteristics of −15 dB were obtained at 31 GHz.

FIG. 35 is a graph showing the electromagnetic wave attenuation characteristics of Example 12. Good absorption characteristics of −15 dB were obtained at 29 GHz.

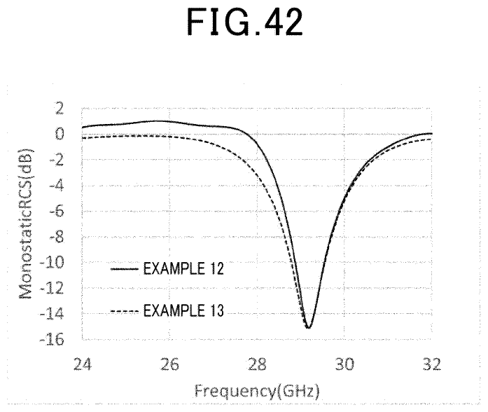

As a result, the amount of electromagnetic wave attenuation of the electromagnetic wave attenuation film according to Example 12, as in FIG. 36, showed good absorption characteristics of −15 dB at 29 GHz. Therefore, the actual measurement of the electromagnetic wave absorption characteristics according to Example 12 matched the simulation value result of the electromagnetic wave absorption characteristics according to Example 13. FIG. 42 is a graph showing the electromagnetic wave attenuation characteristics of Example 12 and Example 13.

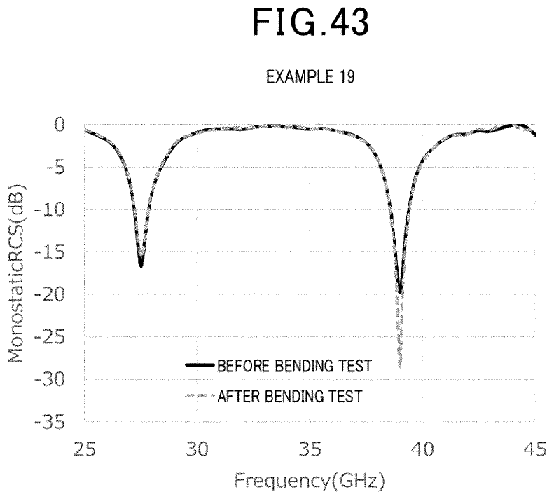

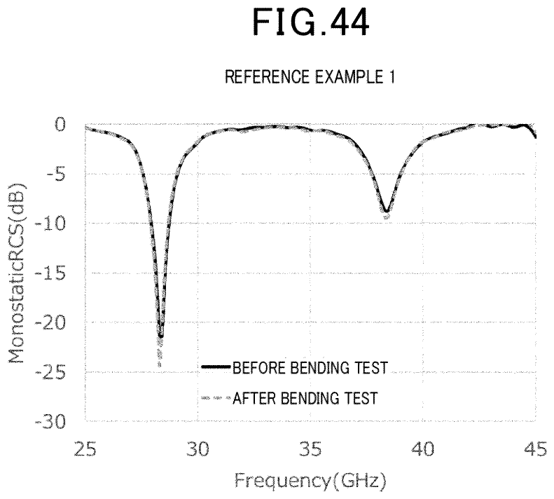

The electromagnetic wave attenuation films according to Example 19 and Reference Example 1, as in Example 4, were also subjected to an actual measurement of the amount of electromagnetic wave attenuation. The evaluation results are shown in Table 7. FIGS. 43 and 44 show graphs of actual measurements of monostatic RCS attenuation at each frequency.

FIG. 43 is a graph showing the electromagnetic wave attenuation characteristics of Example 19. Absorption peaks at 27.5 GHz and 39 GHz (dual band) were observed, and the amount of attenuation at each absorption peak frequency was −17 dB and −20 dB before the bending test, and −16 dB and −29 dB after bending test, thereby showing good absorption characteristics at both frequencies.

FIG. 44 is a graph showing the electromagnetic wave attenuation characteristics of Reference Example 1. Absorption peaks at 28.3 GHz and 38.4 GHz (dual band) were observed, and the amount of attenuation at each absorption peak frequency was −21 dB and −9 dB before the bending test, and −24 dB and −9 dB after bending test.

From the above, it has been shown that by using a configuration of an electromagnetic wave attenuation substrate in which conductive elements are arranged on the front surface and the back surface of a dielectric substrate, not only are positional shifts due to bending reduced, but changes in the electromagnetic wave attenuation characteristics are also reduced.

Furthermore, it has been shown that, in the absorption peak frequency intervals described above, there is a tendency for good absorption characteristics to be obtained when the size of the conductive element on the front surface is made smaller than the conductive elements on the back surface. When the ratio of the higher frequency absorption peak frequency divided by the lower frequency absorption peak frequency (hereinafter referred to as “absorption peak frequency ratio”) is used as an index of the absorption peak frequency interval, Example 19 has a ratio of 1.418, and Reference Example 1 has a ratio of 1.357.

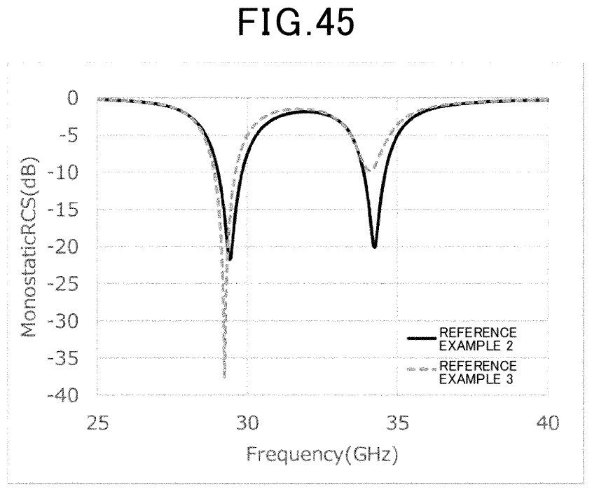

Next, a simulation of the electromagnetic wave absorption characteristics was performed for the electromagnetic wave attenuation films according to Reference Examples 2 and 3. The evaluation results are shown in Table 8. FIG. 45 shows a graph of monostatic RCS attenuation at each frequency.

FIG. 45 is a graph showing the electromagnetic wave attenuation characteristics of Reference Example 2 and Reference Example 3.

Absorption peaks at 29.4 GHz and 34.25 GHz (dual band) were observed in Reference Example 2, and the amount of attenuation at each absorption peak frequency was −22 dB and −20 dB, thereby showing good absorption characteristics at both frequencies. The absorption peak frequency ratio was 1.165.

Absorption peaks at 29.25 GHz and 34.25 GHz (dual band) were observed in Reference Example 3, and the amount of attenuation at each absorption peak frequency was −37 dB and −10 dB, thereby showing good absorption characteristics at both frequencies. The absorption peak frequency ratio was 1.171.

From Reference Examples 2 and 3, it has been shown that, in the absorption peak frequency interval described above, there is a tendency for good absorption characteristics to be obtained when the size of the conductive element on the front surface is made smaller than the conductive elements on the back surface. Although the predetermined absorption peak frequency interval is not particularly limited, when the example of a dual band consisting of a 28 GHz band and a 39 GHz band is considered, it is thought that the above tendency is maintained when the interval is at least the separation between 29.5 GHz and 34 GHz (absorption peak frequency ratio of 1.153 or more).

### (Overall Evaluation)

As a result of producing and evaluating the electromagnetic wave attenuation films of Examples 1 to 19, in the electromagnetic wave attenuation films having thin film conductive layers simultaneously formed on the front surface and the back surface of the dielectric substrate, no positional offset of the thin film conductive layer occurred even after the bending test, and the structure before the test was maintained.

Furthermore, the absorbed frequency was as designed, and an absorption amount of −10 dB was ensured. As a result of the weather resistance test, it was confirmed that there was no degradation of both the top coat layer and the electromagnetic wave attenuation layer, and in particular, by forming the top coat layer, the weather resistance improved, and good characteristics particularly for practical use were obtained.

### Example 20

A laminate sheet was separately prepared by laminating a design-imparting layer provided with a wood grain pattern on a durability-imparting layer, and this was attached to the electromagnetic wave attenuation film according to Example 3 using an adhesive while taking care to not allow air bubbles to enter between the laminate sheet and the thin film conductor layer 30, and this was used as the top coat layer 200 according to the present invention to form the electromagnetic wave attenuation film of Example 20.

As a result, electromagnetic wave attenuation characteristics similar to those of Example 3 were obtained. In addition, when the electromagnetic wave attenuation film of Example 20 was attached next to a wood grain pattern decorative sheet inside a room, the electromagnetic wave attenuation film of Example 20 did not look out of place with the wood grain pattern decorative sheet, and the entire room was given a harmonious wood grain appearance.

### Example 21

A laminate sheet was separately prepared by laminating a design-imparting layer provided with a wood grain pattern on a durability-imparting layer, and this was attached to the electromagnetic wave attenuation film according to Example 10 using an adhesive while taking care to not allow air bubbles to enter between the laminate sheet and the thin film conductor layer 30, and this was used as the top coat layer 200 according to the present invention to form the electromagnetic wave attenuation film of Example 21.

As a result, electromagnetic wave attenuation characteristics similar to those of Example 10 were obtained. In addition, when the electromagnetic wave attenuation film of Example 21 was attached next to a wood grain pattern decorative sheet inside a room, the electromagnetic wave attenuation film of Example 21 did not look out of place with the wood grain pattern decorative sheet, and the entire room was given a harmonious wood grain appearance.

### Example 22

A laminate sheet was separately prepared by laminating a design-imparting layer provided with a marble pattern on a durability-imparting layer, and this was attached to the electromagnetic wave attenuation film according to Example 3 using an adhesive while taking care to not allow air bubbles to enter between the laminate sheet and the thin film conductor layer 30, and this was used as the top coat layer 200 according to the present invention to form the electromagnetic wave attenuation film of Example 22.

As a result, electromagnetic wave attenuation characteristics similar to those of Example 3 were obtained. In addition, when the electromagnetic wave attenuation film of Example 22 was placed next to a marble patterned flooring material in a room, the electromagnetic wave attenuation film of Example 22 did not look out of place with the marble patterned flooring material, and did not detract from the luxurious feel of the marble patterned flooring material in the room.

### Example 23

A laminate sheet was separately prepared by laminating a design-imparting layer provided with a marble pattern on a durability-imparting layer, and this was attached to the electromagnetic wave attenuation film according to Example 10 using an adhesive while taking care to not allow air bubbles to enter between the laminate sheet and the thin film conductor layer 30, and this was used as the top coat layer 200 according to the present invention to form the electromagnetic wave attenuation film of Example 23.

As a result, electromagnetic wave attenuation characteristics similar to those of Example 10 were obtained. In addition, when the electromagnetic wave attenuation film of Example 23 was placed next to a marble patterned flooring material in a room, the electromagnetic wave attenuation film of Example 23 did not look out of place with the marble patterned flooring material and did not detract from the luxurious feel of the marble patterned flooring material in the room.

### COMPARATIVE EXAMPLES

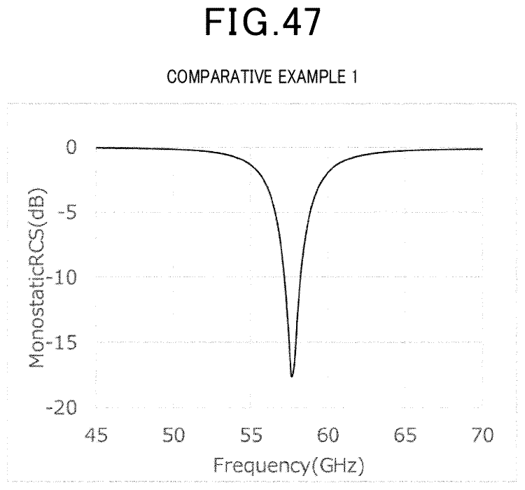

Table 9 shows the structure and evaluation results of the electromagnetic wave attenuation films according to the Comparative Examples. Furthermore, FIGS. 47 to 49 show graphs of monostatic RCS attenuation at each frequency.

TABLE 9

| | | Comparative | | Comparative | | Comparative | |
|---|---|---|---|---|---|---|---|
| | | Example 1 | | Example 2 | | Example 3 | |
| Structure | l (mm) | 1.4 | | 3 | | 2.1 | |
| | a (mm) | 0.5 | | 0.5 | | 0.5 | |
| | l/a | 2.8 | | 6.0 | | 4.2 | |
| | l1 (mm) | — | | — | | — | |
| | a1 (mm) | — | | — | | — | |
| | t (μm) | 50 | | 50 | | 50 | |
| | ts (μm) | 100 | | 100 | | 4 | |
| | tm (nm) | 500 | | 500 | | 500 | |
| | tmb (nm) | 50 | | 50 | | 50 | |
| | h (μm) | — | | — | | — | |
| Evaluation | Positional | Approx. 5 mm | | None | | None | |
| results | shift after | | | | | | |
| | bending test | | | | | | |
| | Absorption | 57 | GHz | 75 | GHz | 79 | GHz |
| | frequency | | | | | | |
| | Absorption | −18 | dB | −9 | dB | −7 | dB |

| | | | |
|---|---|---|---|
| amount | | | |
| Weather | Fair | Fair | Fair |
| resistance test | | | |

| | | | |
|---|---|---|---|
| Overall evaluation | Poor | Poor | Poor |

### Comparative Example 1

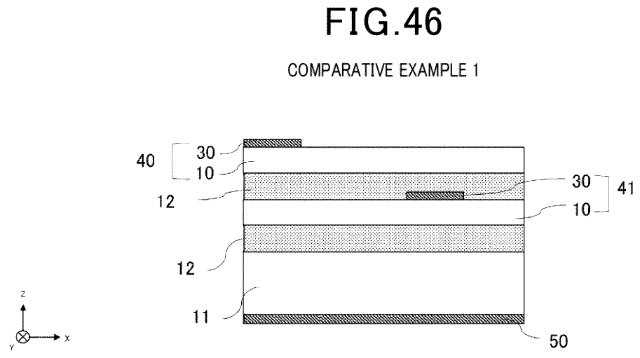

The electromagnetic wave attenuation film of Comparative Example 1 differs from the examples having a configuration in which thin film conductive layers are formed on both the front surface and back surface of a dielectric substrate (electromagnetic wave attenuating substrate) in that it has a laminated structure. FIG. 46 is a schematic diagram showing a portion of a cross-section of the electromagnetic wave attenuation film of Comparative Example 1. The same configurations as those in FIG. 2 or 19 will be omitted. The laminate has a configuration in which an upper lamination layer 40 and a lower lamination layer 41 are laminated, in which thin film conductive layer 30 is formed only on the front surface of dielectric substrate 10. The structure of the electromagnetic wave attenuation film of Comparative Example 1 is shown in Table 9.

### <Manufacturing Method>

In accordance with Example 1, two lamination layers were prepared, namely an upper lamination layer 40 and a lower lamination layer 41, in which the thin film conductive layer 30 was arranged on only the front side of the dielectric substrate 10. The lower lamination layer 41 was attached to the back surface side of the upper lamination layer 40 via an acrylic pressure-sensitive adhesive layer 12. Then, a PET film having a thickness of 100 μm was laminated via the pressure-sensitive adhesive layer 12 to form the support layer 11, and an aluminum flat plate inductor 50 was further attached to the back surface of the support layer 11 using an adhesive layer to produce an electromagnetic wave attenuation film formed of a multi-layer laminate.

### <Evaluation Method and Results>

In accordance with Example 1, the electromagnetic wave attenuation film was subjected to a bending test, and the electromagnetic wave attenuation characteristics and weather resistance were evaluated. The evaluation results are shown in Table 9.

After conducting the bending test with respect to the electromagnetic wave attenuation film formed by the multi-layer laminate of Comparative Example 1, the position of the conductive elements of the test piece was observed, and as a result, a shift occurred between the film of the upper lamination layer 40 and the film of the lower lamination layer 41, and the arrangement positions of the conductive elements 30 in the upper layer and the lower layer were shifted by approximately 5 mm from before the test.

FIG. 47 is a graph showing the electromagnetic wave attenuation characteristics of Comparative Example 1. In contrast to a designed value of the target absorption frequency of absorption near 75 GHz, the electromagnetic wave absorption sheet produced by lamination had an absorption peak frequency of 57 GHz, which was significantly different from the designed value.

In terms of the weather resistance, when wiped with a cotton cloth, the thin metal layer peeled off, and the results were not particularly good.

### Comparative Examples 2 and 3

Except for some differences in the dimensions of the components of the electromagnetic wave absorption film, Comparative Examples 2 and 3 have the same configuration as the electromagnetic wave absorption film according to Example 1 and the like, and therefore, the differences will be mainly described.

Comparative Example 2 has a structure such that, when a distance in the plane direction between the center of gravity of the conductive elements on the front surface and the back surface of the dielectric substrate is 1, and the shortest distance from the center of gravity of the conductive elements to a plate end portion is a, the conductive elements are formed with a positional relationship that does not satisfy equation (1) below.

$$I ≦ 5.2 a \qquad ( 1 )$$

Comparative Example 3 has a structure in which the film thickness of the support layer is less than 5 μm. The structure of the electromagnetic wave attenuation film of Comparative Examples 2 and 3 is shown in Table 9.

### <Manufacturing Method>

In accordance with Example 1, the thin film conductive layers were formed on the front surface and the back surface of the dielectric substrate, the support layer was formed via a pressure-sensitive adhesive layer on the thin film conductive layer on the back surface side, and then the flat plate inductor was formed on the back surface of the support layer.

### <Evaluation Method and Results>

In accordance with Example 1, the electromagnetic wave attenuation film was subjected to a bending test, evaluation of the electromagnetic wave attenuation characteristics, and subjected to a weather resistance test. The evaluation results are shown in Table 7.

In terms of the bending test, in both Comparative Examples 2 and 3, no positional shift of the thin film conductive layers occurred even after the bending test.

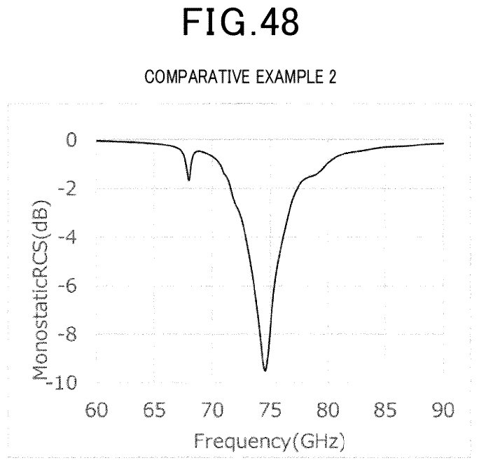

FIG. 48 is a graph showing the electromagnetic wave attenuation characteristics of Comparative Example 2. As a result of 1/a being 6.0 and not satisfying the relationship in equation (1), resonant coupling did not occur between the conductive elements on the front surface and the back surface, and as a result, the absorption amount did not reach the target of −10 dB.

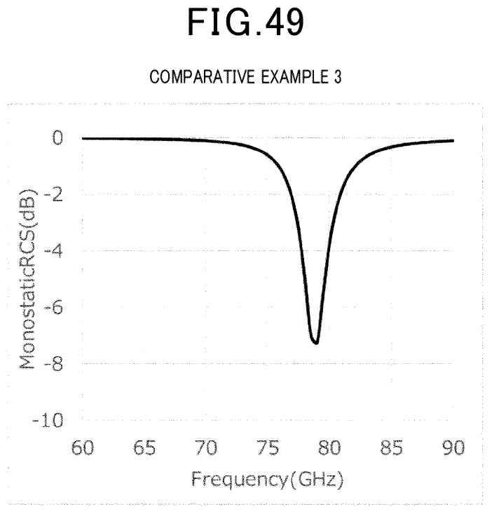

FIG. 49 is a graph showing the electromagnetic wave attenuation characteristics of Comparative Example 3. As in Comparative Example 3, when the film thickness of the support layer formed on the back surface of the conductive elements on the back surface of the dielectric substrate was 4 m, which is thinner than 5 m, the absorption amount did not reach the target of −10 dB. For this reason, the thickness of the support layer is preferably 5 μm (0.005 mm) or more.

In terms of the weather resistance, when wiped with a cotton cloth, the thin metal layer peeled off, and the results were not particularly good.

Although the embodiments of the present invention have been described in detail with reference to the drawings, specific configurations are not limited to the embodiment, and various modifications and combinations of the configurations can be made without departing from the spirit of the present invention. A number of modifications are illustrated below, but these are not exhaustive, and other modifications are also possible. Two or more of the modifications may also be combined as appropriate.

In the first embodiment, the aspects used in the second embodiment, such as the frequency bands and the metal type of the conductive elements, can be used as appropriate.

In the present invention, the form of the flat plate inductor is not limited to being formed on the entire back surface. For example, a plurality of conductive elements may be arranged in the same manner as on the front surface or may be arranged in a lattice pattern.

In the present invention, the shape of the conductive elements is not limited to a square and can be set to various shapes such as a circle (including an ellipse), a polygon other than a square, various polygons with rounded corners, and an irregular shape. The total area of the conductive elements in the projected area of the front surface is preferably 20% or more.

In this way, electromagnetic waves can be efficiently attenuated.

The electromagnetic wave attenuation film according to the present invention may have a configuration in which no flat plate inductor is provided on the back surface. For example, if the object to which the back surface is joined is a metal, the second and third mechanisms can be exhibited without any problem by the metal surface of the joining object even if a flat plate inductor is not provided. In such a case, the back surface may be provided with an attachment layer such as an pressure-sensitive adhesive layer that can be bonded to the object.

In the electromagnetic wave attenuation film according to the present invention, it is not essential that parameters such as the structural period, the dimensions of the conductive elements, and the like, are completely consistent in all parts. For example, even when the above parameters vary within a tolerance range in the manufacturing process (generally 5% or so), this is also included in the meaning of having the “same shape and same size” in the present invention. Furthermore, a “predetermined range of values” can be a range of values that has some regularity. This regularity can be a Gaussian distribution, a binomial distribution, a random or pseudorandom distribution with equal frequency within a certain area, or a range of tolerances in the manufacturing process.

In the electromagnetic wave attenuation film of the present invention, a release layer may be provided on a supporting substrate, and then the electromagnetic wave attenuation film of the first embodiment and the second embodiment may be provided, and an adhesive, a pressure-sensitive adhesive, or the like may be provided to form a transfer foil.

As a result of forming a transfer foil, it is possible to make the film even thinner, further improving the followability and enabling transfer to complex shapes, thereby widening the range of application of the electromagnetic wave attenuation film of the present invention.

In the examples above, the attenuation of electromagnetic waves has been investigated, but it is known that conductors that attenuate specific electromagnetic waves can be used as an antenna that receives radio waves. Therefore, the embodiments described above can also be used as a receiving antenna. Furthermore, in the embodiments described above, since a quantum with zero momentum can be captured in a two-dimensional system, it is considered to be possible to use the quantum states of the conductive elements as elements to calculate or record data.

As described above, the embodiment of the present invention has a mechanism of interaction with electromagnetic waves that is different from that of the conventional technique, and therefore, a product that exhibits an equivalent mechanism should be considered to be substantially using an embodiment of the present invention.

The possible aspects of the content of the present invention are described below, but the present invention is not limited thereto.

### (Aspect 1)

An electromagnetic wave attenuation film comprising:
an electromagnetic wave attenuation substrate provided with a dielectric substrate having a front surface and a back surface, and thin film conductive layers arranged on both the front surface and the back surface of the electromagnetic wave attenuation substrate;
a support layer arranged on the back surface of the electromagnetic wave attenuation substrate; and
a flat plate inductor arranged on a back surface of the support layer; wherein
the thin film conductive layers include a plurality of conductive elements.

### (Aspect 2)

The electromagnetic wave attenuation film according to aspect 1, wherein
the conductive elements are arranged periodically, and
when a distance in a plane direction between a center of gravity of the conductive elements on the front surface and the back surface of the dielectric substrate is 1, and a shortest distance from the center of gravity of the conductive elements to a plate end portion is a, equation (1) below is satisfied.

$$I ≦ 5.2 a \qquad ( 1 )$$

### (Aspect 3)

The electromagnetic wave attenuation film according to aspect 1 or 2, wherein
the conductive elements are arranged periodically, and
a film thickness of the support layer is 0.005 mm or more.

### (Aspect 4)

The electromagnetic wave attenuation film according to any one of aspects 1 to 3, wherein
the conductive elements are arranged periodically, and
when a thickness of the conductive elements is T, and a skin depth is d, equation (4) below is satisfied.

$$- 2 ≦ ln ( T / D ) ≦ 1 \qquad ( 4 )$$

### (Aspect 5)

The electromagnetic wave attenuation film according to any one of aspects 1 to 4, wherein
the conductive elements are arranged periodically, and
when a distance in a plane direction between a center of gravity of the conductive elements on the front surface and the back surface of the dielectric substrate is 1, and a shortest distance from the center of gravity of the conductive elements to a plate end portion is a, electromagnetic wave attenuation performance is exhibited at multiple frequencies as a result of mixing a combination of conductive elements on the front surface and the back surface of the dielectric substrate satisfying equation (6) below, and a combination of conductive elements on the front surface and the back surface of the dielectric substrate satisfying equation (7) below.

$$I < 2 a \qquad ( 6 )$$

$$I ≧ 2 a \qquad ( 7 )$$

### (Aspect 6)

The electromagnetic wave attenuation film according to any one of aspects 1 to 5, wherein the thin film conductive layer and the flat plate inductor are separated in a thickness direction of the dielectric substrate or the support layer.

### (Aspect 7)

The electromagnetic wave attenuation film according to any one of aspects 1 to 6, wherein a front surface and a back surface of the thin film conductive layer on the front surface of the dielectric substrate is provided with a blackening layer.

### (Aspect 8)

The electromagnetic wave attenuation film according to any one of aspects 1 to 7, wherein a front surface and a back surface of the thin film conductive layer on the back surface of the dielectric substrate is provided with a blackening layer.

### (Aspect 9)

The electromagnetic wave attenuation film according to any one of aspects 1 to 8, comprising a top coat layer on a front surface side of the electromagnetic wave attenuation substrate.

### (Aspect 10)

The electromagnetic wave attenuation film according to aspect 9, wherein the top coat layer is impedance-matched to an air layer through which an electromagnetic wave propagates.

### (Aspect 11)

The electromagnetic wave attenuation film according to aspect 9 or 10, wherein the top coat layer has, as a main component, an acrylic resin composition containing cyclohexyl (meth)acrylate as a monomer component.

### (Aspect 12)

The electromagnetic wave attenuation film according to any one of aspects 9 to 11, wherein the top coat layer contains an ultraviolet absorber or an ultraviolet light scattering agent in an acrylic resin composition.

### (Aspect 13)

The electromagnetic wave attenuation film according to any one of aspects 1 to 12, wherein the thin film conductive layers are composed of one of silver, copper, and aluminum.

### (Aspect 14)

The electromagnetic wave attenuation film according to any one of aspects 1 to 13, wherein the thin film conductive layers are capable of capturing an electromagnetic wave incident from a front surface side of the dielectric substrate.

### (Aspect 15)

The electromagnetic wave attenuation film according to any one of aspects 1 to 14, wherein the conductive elements are planar elements, and have a pair of opposing sides.

### (Aspect 16)

The electromagnetic wave attenuation film according to aspect 15, wherein a length of a pair of opposing sides of the planar elements is 0.25 mm or more and 4 mm or less.

### (Aspect 17)

The electromagnetic wave attenuation film according to any one of aspects 1 to 16, wherein a thickness of the dielectric substrate is sufficiently thin with respect to an attenuation center wavelength.

### (Aspect 18)

The electromagnetic wave attenuation film according to aspect 17, wherein a thickness of the dielectric substrate is less than one-tenth of an attenuation center wavelength.

### (Aspect 19)

The electromagnetic wave attenuation film according to aspect 2, wherein a size of the conductive elements on the front surface of the dielectric substrate is smaller than a size of the conductive elements on the back surface of the dielectric substrate, and have absorption peak frequencies that are different from each other.

### (Aspect 20)

The electromagnetic wave attenuation film according to aspect 19, wherein an absorption peak frequency ratio between the absorption peak frequencies that are different from each other is 1.153 or more.

### (Aspect 21)

A manufacturing method of an electromagnetic wave attenuation film comprising:
a step for performing simultaneous front and back formation of a predetermined repeating pattern formed of a plurality of conductive elements on a front surface of a dielectric substrate (hereinafter referred to as “front surface pattern”), and a predetermined repeating pattern formed of a plurality of conductive elements on a back surface of the dielectric substrate (hereinafter referred to as “back surface pattern”);
a step for laminating a support layer on the back surface of the dielectric substrate on which patterns have been formed on the front and back; and
a step for forming a flat plate inductor on a back surface of the support layer.

### (Aspect 22)

The manufacturing method of an electromagnetic wave attenuation film according to aspect 21, comprising a step for attaching, to the back surface of the dielectric substrate on which the front surface pattern and the back surface pattern have been formed, a front surface of the support layer on which the flat plate inductor has been formed.

### (Aspect 23)

The manufacturing method of an electromagnetic wave attenuation film according to aspect 21 or 22, wherein a shape and/or a position of the front surface pattern and the back surface pattern are different from each other.

### (Aspect 24)

The manufacturing method of an electromagnetic wave attenuation film according to any one of aspects 21 to 23, wherein when a separation in a plane direction between a center of gravity of the conductive elements on the front surface and the back surface of the dielectric substrate is 1, and a shortest distance from the center of gravity of the conductive elements to a plate end portion is a, equation (1) below is satisfied.

$$I ≦ 5.2 a \qquad ( 1 )$$

### (Aspect 25)

The manufacturing method of an electromagnetic wave attenuation film according to any one of aspects 21 to 24, wherein a film thickness of the support layer is 0.015 mm or more and 0.15 mm or less.

### (Aspect 26)

The manufacturing method of an electromagnetic wave attenuation film according to any one of aspects 21 to 25, wherein the conductive elements are formed such that, when a thickness thereof is T, and a skin depth is d, equation (4) below is satisfied.

$$- 2 ≦ ln ( T / D ) ≦ 1 \qquad ( 4 )$$

### (Aspect 27)

The manufacturing method of an electromagnetic wave attenuation film according to any one of aspects 21 to 26, wherein when a separation in a plane direction between a center of gravity of the conductive elements on the front surface and the back surface of the dielectric substrate is 1, and a shortest distance from the center of gravity of the conductive elements to a plate end portion is a, a combination of conductive elements on the front surface and the back surface of the dielectric substrate satisfying equation (6) below, and a combination of conductive elements on the front surface and the back surface of the dielectric substrate satisfying equation (7) below are formed so as to be mixed.

$$I < 2 a \qquad ( 6 )$$

$$I ≧ 2 a \qquad ( 7 )$$

### (Aspect 28)

The manufacturing method of an electromagnetic wave attenuation film according to any one of aspects 21 to 27, comprising a step for performing blackening treatment of a surface of the conductive elements on the front surface of the dielectric substrate on a side opposite to the conductive elements.

### (Aspect 29)

The manufacturing method of an electromagnetic wave attenuation film according to any one of aspects 21 to 28, comprising a step for performing blackening treatment of a surface of the conductive elements on the back surface of the dielectric substrate on a side opposite to the conductive elements.

### (Aspect 30)

The manufacturing method of an electromagnetic wave attenuation film according to any one of aspects 21 to 29, comprising a step for forming a top coat layer on the front surface of the dielectric substrate, on which the front surface pattern has been formed.

### (Aspect 31)

The manufacturing method of an electromagnetic wave attenuation film according to aspect 30, wherein the top coat layer is formed so as to be impedance-matched to an air layer that propagates an electromagnetic wave.

### (Aspect 32)

The manufacturing method of an electromagnetic wave attenuation film according to aspect 30 or 31, wherein the top coat layer has, as a main component, an acrylic resin composition containing cyclohexyl (meth)acrylate as a monomer component.

### (Aspect 33)

The manufacturing method of an electromagnetic wave attenuation film according to any one of aspects 30 to 32, wherein the top coat layer contains an ultraviolet absorber or an ultraviolet light scattering agent in an acrylic resin composition.

### (Aspect 34)

The manufacturing method of an electromagnetic wave attenuation film according to any one of aspects 21 to 33, wherein the front surface pattern and the back surface pattern are formed using one of silver, copper, and aluminum.

### (Aspect 35)

The manufacturing method of an electromagnetic wave attenuation film according to any one of aspects 21 to 34, wherein the front surface pattern and the back surface pattern are formed having a configuration that is capable of capturing an electromagnetic wave incident from the front surface side.

### (Aspect 36)

The manufacturing method of an electromagnetic wave attenuation film according to any one of aspects 21 to 35, wherein the conductive elements are formed with a shape having a pair of opposing sides.

### (Aspect 37)

The manufacturing method of an electromagnetic wave attenuation film according to aspect 36, wherein a pair of opposing sides of the conductive elements is formed having a length of 0.25 mm or more and 4 mm or less.

### (Aspect 38)

The manufacturing method of an electromagnetic wave attenuation film according to any one of aspects 21 to 37, wherein a thickness of the dielectric substrate is sufficiently thin with respect to an attenuation center wavelength.

### (Aspect 39)

The manufacturing method of an electromagnetic wave attenuation film according to aspect 38, wherein a thickness of the dielectric substrate is less than one-tenth of an attenuation center wavelength.

### (Aspect 40)

The manufacturing method of an electromagnetic wave attenuation film according to any one of aspects 21 to 39, wherein the front surface pattern and the back surface pattern are formed by a photolithography method.

### (Aspect 41)

The manufacturing method of an electromagnetic wave attenuation film according to aspect 24, wherein a size of the conductive elements on the front surface of the dielectric substrate is smaller than a size of the conductive elements on the back surface of the dielectric substrate and have absorption peak frequencies that are different from each other.

### (Aspect 42)

The manufacturing method of an electromagnetic wave attenuation film according to aspect 41, wherein an absorption peak frequency ratio between the absorption peak frequencies that are different from each other is 1.153 or more.

[Reference Signs List]1, 61 Electromagnetic wave attenuation film; 10, 62 Dielectric substrate; 10a, 62a Front surface; 10b, 62b Back surface; 20, 60 Electromagnetic wave attenuation substrate; 30, 30A, 31, 31A Thin film conductive layer, conductive element; 32, 33, 34, 35, 36, 37 Blackening layer; 11 Support layer; 12, 13 Pressure-sensitive adhesion layer; 40 Upper lamination layer; 41 Lower lamination layer; 50 Flat plate inductor; 200 Top coat layer; 301 Substrate; 302 Unwinding portion; 303 Winding portion; 304, 305 Photomask; 306, 307 Scanning camera.

What is claimed is:

1. An electromagnetic wave attenuation film, comprising:
an electromagnetic wave attenuation substrate provided with a dielectric substrate having a front surface and a back surface, and thin film conductive layers arranged on both the front surface and the back surface of the electromagnetic wave attenuation substrate;
a support layer arranged on the back surface of the electromagnetic wave attenuation substrate; and
a flat plate inductor arranged on a back surface of the support layer; wherein
the thin film conductive layers include a plurality of conductive elements.

2. The electromagnetic wave attenuation film of claim 1, wherein
the conductive elements are arranged periodically, and
when a distance in a plane direction between a center of gravity of the conductive elements on the front surface and the back surface of the dielectric substrate is 1, and a shortest distance from the center of gravity of the conductive elements to a plate end portion is a, equation (1) below is satisfied.
$$I ≦ 5.2 a \qquad ( 1 )$$

3. The electromagnetic wave attenuation film of claim 1, wherein
the conductive elements are arranged periodically, and
when a thickness of the conductive elements is T, and a skin depth is d, equation (4) below is satisfied.
$$- 2 ≦ ln ( T / d ) ≦ 1 \qquad ( 4 )$$

4. The electromagnetic wave attenuation film of claim 1, wherein
the conductive elements are arranged periodically, and
when a distance in a plane direction between a center of gravity of the conductive elements on the front surface and the back surface of the dielectric substrate is 1, and a shortest distance from the center of gravity of the conductive elements to a plate end portion is a, electromagnetic wave attenuation performance is exhibited at multiple frequencies as a result of mixing a combination of conductive elements on the front surface and the back surface of the dielectric substrate satisfying equation (6) below, and a combination of conductive elements on the front surface and the back surface of the dielectric substrate satisfying equation (7) below.
$$I < 2 a \qquad ( 6 )$$
$$I ≧ 2 a \qquad ( 7 )$$

5. The electromagnetic wave attenuation film of claim 1, wherein
a front surface and a back surface of the thin film conductive layer on the front surface of the dielectric substrate is provided with a blackening layer.

6. The electromagnetic wave attenuation film of claim 1, wherein
a front surface and a back surface of the thin film conductive layer on the back surface of the dielectric substrate is provided with a blackening layer.

7. The electromagnetic wave attenuation film of claim 1, wherein
the thin film conductive layers are capable of capturing an electromagnetic wave incident from a front surface side of the dielectric substrate.

8. The electromagnetic wave attenuation film of claim 1, wherein
the conductive elements are planar elements and have a pair of opposing sides.

9. The electromagnetic wave attenuation film of claim 1, wherein
a thickness of the dielectric substrates is less than one-tenth of an attenuation center wavelength.

10. The electromagnetic wave attenuation film of claim 2, wherein
a size of the conductive elements on the front surface of the dielectric substrate is smaller than a size of the conductive elements on the back surface of the dielectric substrate and have absorption peak frequencies that are different from each other.

11. The electromagnetic wave attenuation film of claim 10, wherein
an absorption peak frequency ratio between the absorption peak frequencies that are different from each other is 1.153 or more.

12. A manufacturing method of an electromagnetic wave attenuation film, comprising the steps of:
a step for performing simultaneous front and back formation of a predetermined repeating pattern formed of a plurality of conductive elements on a front surface of a dielectric substrate (hereinafter referred to as “front surface pattern”), and a predetermined repeating pattern formed of a plurality of conductive elements on a back surface of the dielectric substrate (hereinafter referred to as “back surface pattern”);
a step for laminating a support layer on the back surface of the dielectric substrate on which patterns have been formed on the front and back; and
a step for forming a flat plate inductor on a back surface of the support layer.

13. The manufacturing method of an electromagnetic wave attenuation film of claim 12, further comprising
a step for attaching, to the back surface of the dielectric substrate on which the front surface pattern and the back surface pattern have been formed, a front surface of the support layer on which the flat plate inductor has been formed.

14. The manufacturing method of an electromagnetic wave attenuation film of claim 12, wherein
a shape and/or a position of the front surface pattern and the back surface pattern are different from each other.

15. The manufacturing method of an electromagnetic wave attenuation film of claim 12, wherein
the front surface pattern and the back surface pattern are formed by a photolithography method.
